(19) United States
(12) Patent Application Publication
(10) Pub. No.: US 2026/0026206 A1
(43) Pub. Date: Jan. 22, 2026

(54) DISPLAY PANEL, ELECTRONIC DEVICE INCLUDING THE SAME, AND METHOD OF MANUFACTURING DISPLAY PANEL

(71) Applicant: Samsung Display Co., Ltd., Yongin-si (KR)

(72) Inventors: DOKEUN SONG, Yongin-si (KR); SUKYOUNG YANG, Yongin-si (KR); SAMTAE JEONG, Yongin-si (KR); JOONYONG PARK, Yongin-si (KR)

(21) Appl. No.: 19/209,441

(22) Filed: May 15, 2025

(30) Foreign Application Priority Data
Jul. 17, 2024 (KR) 10-2024-0094691
Dec. 24, 2024 (KR) 10-2024-0195975

(51) Int. Cl. H10K 59/123; H10K 59/12; H10K 59/124

(52) U.S. Cl. CPC H10K 59/123; H10K 59/1201; H10K 59/124

(57) ABSTRACT

A display panel includes a first transistor, a lower insulating layer on the first transistor, a first connection electrode on the lower insulating layer and connected to the first transistor through a first contact hole in the lower insulating layer, and a light emitting element on the first connection electrode and including an anode electrically connected to the first connection electrode, wherein the first connection electrode includes a first connection layer having a portion in the first contact hole and connected to the first transistor, a second connection layer on the first connection layer and including a metal, and a first insulating pattern on the second connection layer, the second connection layer includes a first portion on the lower insulating layer and a second portion connected to the first portion, the second portion having a portion in the first contact hole, and has a step difference from the first portion.

### CROSS-REFERENCE TO RELATED APPLICATIONS

This application claims priority to and the benefit of Korean Patent Application No. 10-2024-0094691, filed on Jul. 17, 2024, and Korean Patent Application No. 10-2024-0195975, filed on Dec. 24, 2024, in the Korean Intellectual Property Office, the entire disclosures of which are incorporated by reference herein.

### BACKGROUND

The present disclosure relates to a display panel, an electronic device including the same, and a method of manufacturing a display device, and more particularly, relates to a display panel having improved reliability, an electronic device including the same, and a method of manufacturing the same.

Generally, electronic devices such as smartphones, digital cameras, laptop computers, navigation systems, and smart televisions that provide images to a user include display devices for displaying the images. The display device generates the image and provides the generated image to the user through a display screen.

The display device includes a display panel including a plurality of pixels for generating an image, a scan driver for applying scan signals to the pixels, and a data driver for applying data voltages to the pixels. The pixels receive the data voltages in response to the scan signals and generate an image using the data voltages.

Each of the pixels includes a light emitting element and a plurality of transistors connected to the light emitting element. The light emitting element is driven by the transistors to generate light. From among the transistors, the driving transistor is connected to the light emitting element through a connection electrode. The connection electrode is connected to the driving transistor through a contact hole defined in an insulating layer. An area occupied by the contact hole in each of the pixels is limited, and thus development of technology for precisely manufacturing the contact hole is required.

### SUMMARY

Embodiments of the present disclosure provide a display panel having improved contact reliability of a first connection electrode connecting a first transistor to a light emitting element, an electronic device including the same, and a method of manufacturing the same.

According to one or more embodiments, a display panel includes a first transistor, a lower insulating layer on the first transistor, a first connection electrode on the lower insulating layer and connected to the first transistor through a first contact hole in the lower insulating layer, and a light emitting element on the first connection electrode and including an anode electrically connected to the first connection electrode, wherein the first connection electrode includes a first connection layer having a portion in the first contact hole and connected to the first transistor, a second connection layer on the first connection layer and including a metal, and a first insulating pattern on the second connection layer, the second connection layer includes a first portion on the lower insulating layer, and a second portion connected to the first portion, the second portion having a portion in the first contact hole, and has a step difference from the first portion, the first insulating pattern is on the second portion, and a first upper surface of the first insulating pattern is aligned with a second upper surface of the first portion.

The first insulating pattern may include at least one of a silicon oxide, a silicon nitride, or a silicon oxy nitride.

The first connection electrode may further include a third connection layer on the first upper surface and the second upper surface, the third connection layer including a metal.

The third connection layer may include a first connection portion on the first upper surface and the second upper surface and a second connection portion connected to the first portion and located on an upper surface of the lower insulating layer.

The lower insulating layer may include an exposed upper surface not overlapping the first connection layer and the second connection layer, and the third connection layer may be on the first upper surface and the second upper surface and may not overlap the exposed upper surface of the lower insulating layer.

The display panel may further include a first upper insulating layer on the first connection electrode and a second connection electrode on the first upper insulating layer and connected to the first connection electrode through a second contact hole in the first upper insulating layer.

The second connection electrode may include a first additional connection layer in the second contact hole and connected to the first connection electrode, a second additional connection layer on the first additional connection layer and including a metal, and a second insulating pattern on the second additional connection layer.

The second connection layer may be directly on the first connection layer, and the first insulating pattern may be directly on the second connection layer.

The first connection layer may include a transparent conductive oxide.

The light emitting element may further include a light emitting layer on the anode and a cathode on the light emitting layer.

The first contact hole may include an inner surface having a predetermined inclination with respect to an upper surface of the first transistor, the second portion may include a (2-1)^{th} portion on the inner surface of the first contact hole and a (2-2)^{th} portion on the upper surface of the first transistor, and the first insulating pattern may fill a space by the (2-1)^{th} portion and the (2-2)^{th} portion.

The lower insulating layer may include an exposed upper surface not overlapping the first connection layer and the second connection layer, and the first insulating pattern may not overlap the exposed upper surface on a plane.

The display panel may further include a second transistor on a layer between the first transistor and the light emitting element, connected to a first gate electrode of the first transistor and a data line, and switched by a write scan signal, wherein a portion of the first connection electrode may be on a same layer as a second gate electrode of the second transistor.

A side surface of the first connection layer and a side surface of the second connection layer may be aligned with each other.

According to one or more embodiments, an electronic device includes a display panel and a case in which the display panel is accommodated, wherein the display panel includes a first transistor, a lower insulating layer on the first transistor, a first connection electrode on the lower insulating layer and connected to the first transistor through a contact hole in the lower insulating layer, and a light emitting element on the first connection electrode and including an anode electrically connected to the first connection electrode, the first connection electrode includes a first connection layer in the contact hole and connected to the first transistor, a second connection layer on the first connection layer, and a first insulating pattern on the second connection layer, the second connection layer includes a first portion on the lower insulating layer and a second portion connected to the first portion, located in the contact hole, and having a step difference from the first portion, the first insulating pattern is on the second portion, and a first upper surface of the first insulating pattern is aligned with a second upper surface of the first portion.

According to one or more embodiments, a method of manufacturing a display panel includes an operation of forming a lower insulating layer on a base layer on which a first transistor is located, an operation of forming a first contact hole, through which a portion of an upper surface of the first transistor is exposed, on the lower insulating layer, an operation of forming a first preliminary connection layer connected to the first transistor through the first contact hole on the lower insulating layer, an operation of forming a second preliminary connection layer including a metal on the first preliminary connection layer, an operation of forming a preliminary insulating layer on the second preliminary connection layer, a first patterning operation of forming a first insulating pattern and a second connection layer by patterning the preliminary insulating layer and the second preliminary connection layer, and a second patterning operation of forming a first connection layer by patterning the first preliminary connection layer using the second connection layer as a mask, wherein the second connection layer includes a first portion on the lower insulating layer and a second portion connected to the first portion, located in the first contact hole, and having a step difference from the first portion, the first insulating pattern is on the second portion, and a first upper surface of the first insulating pattern is aligned with a second upper surface of the first portion.

The first patterning operation may include an operation of etching portions of the preliminary insulating layer and the second preliminary connection layer together, and the second patterning operation may include an operation of wet etching the first preliminary connection layer.

The method may include, after the second patterning operation, an operation of forming a third connection layer on the first upper surface and the second upper surface,, the third connection layer including a metal.

The method may further include an operation of forming a first upper insulating layer on the second connection layer and the first insulating pattern and provided with a second contact hole and an operation of forming a second connection electrode electrically connected to the second connection layer through the second contact hole in the first upper insulating layer.

After the second patterning operation, a side surface of the first connection layer and a side surface of the second connection layer may be aligned with each other.

### BRIEF DESCRIPTION OF THE DRAWINGS

The above and other aspects and features of the present disclosure will become apparent by describing in detail embodiments thereof with reference to the accompanying drawings.

FIG. 1 is a perspective view of an electronic device according to one or more embodiments of the present disclosure.

FIG. 2 is a block diagram of the electronic device according to one or more embodiments of the present disclosure.

FIG. 3 is a view illustrating, by way of example, a cross section of a display device included in the electronic device illustrated in FIGS. 1 and 2.

FIG. 4 is a view illustrating, by way of example, a cross section of a display panel illustrated in FIG. 3.

FIG. 5 is a plan view of the display device illustrated in FIG. 3.

FIG. 6A is a perspective view illustrating an electronic device according to one or more embodiments of the present disclosure.

FIG. 6B is an exploded perspective view of the electronic device illustrated in FIG. 6A.

FIG. 7 illustrates an equivalent circuit of one of the pixels illustrated in FIG. 5.

FIG. 8 is a cross-sectional view of one of the pixels illustrated in FIG. 7.

FIGS. 9A-9E are enlarged cross-sectional views of portions of one pixel illustrated in FIG. 8.

FIG. 10 is a flowchart of a method of manufacturing a display panel according to one or more embodiments.

FIGS. 11A-11I are cross-sectional views sequentially illustrating operations of the method of manufacturing a display panel according to one or more embodiments.

### DETAILED DESCRIPTION

Because the present disclosure can be variously modified and has various forms, embodiments thereof will be illustrated in the drawings and will be described herein in detail. However, it should be understood that the present disclosure is not limited to any specific embodiments and includes all changes, equivalents, and substitutes included in the spirit and scope of the present disclosure.

In the specification, the expression that a first component (or area, layer, part, portion, etc.) is “disposed on”, “connected with,” or “coupled to” a second component means that the first component is directly disposed on/connected with/coupled to the second component or means that a third component is interposed therebetween.

In the present disclosure, the expression “directly disposed” may mean that there is no layer, no film, no area, no plate, and/or the like added between a part such as a layer, a film, an area, and a plate, and other parts. For example, the expression “directly disposed” may mean that an additional member such as an adhesive member is not disposed between two layers or two members.

The same reference numerals refer to the same components. Further, in the drawings, the thickness, the ratio, and the dimension of components are exaggerated for effective description of technical contents. The expression “and/or” includes one or more combinations in which associated components are defined.

Although the terms “first”, “second”, etc. may be used to describe various components, the components should not be limited by the terms. The terms are only used to distinguish one component from another component. For example, without departing from the spirit and scope of the present disclosure, a first component may be referred to as a second component, and similarly, the second component may be also referred to as the first component. Singular expressions include plural expressions unless clearly otherwise indicated in the context.

Also, the terms “under”, “below”, “on”, “above”, etc. are used to describe the correlation of components illustrated in drawings. The terms that are relative in concept are described based on a direction illustrated in drawings. In the specification, the expression “disposed on” may refer to a case in which a first member is disposed under as well as on a second member.

It will be understood that the terms “include”, “comprise”, “have”, etc. specify the presence of features, numbers, steps, operations, elements, and/or components, described in the specification, or a combination thereof, and do not exclude in advance the presence or additional possibility of one or more other features, numbers, steps, operations, elements, or components or a combination thereof.

Unless otherwise defined, all terms (including technical terms and scientific terms) used in the present specification have the same meaning as commonly understood by those skilled in the art to which the present disclosure belongs. Furthermore, terms such as terms defined in the dictionaries commonly used should be interpreted as having a meaning consistent with the meaning in the context of the related technology and should not be interpreted in overly ideal or overly formal meanings unless explicitly defined herein.

For the purposes of the present disclosure, expressions such as “at least one of,” “one of,” and “selected from,” when preceding a list of elements, modify the entire list of elements and do not modify the individual elements of the list. For example, “at least one of X, Y, and Z,” “at least one of X, Y, or Z,” and “at least one selected from the group consisting of X, Y, and Z” may be construed as X only, Y only, Z only, any combination of two or more of X, Y, and Z, such as, for instance, XYZ, XYY, XZ, YZ, and ZZ, or any variation thereof. Similarly, the expression such as “at least one of A and/or B” may include A, B, or A and B. As used herein, the term “and/or” includes any and all combinations of one or more of the associated listed items. For example, the expression such as “A and/or B” may include A, B, or A and

B. Further, the use of “may” when describing embodiments of the present disclosure refers to “one or more embodiments of the present disclosure”.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

Hereinafter, embodiments of the present disclosure will be described with reference to the accompanying drawings.

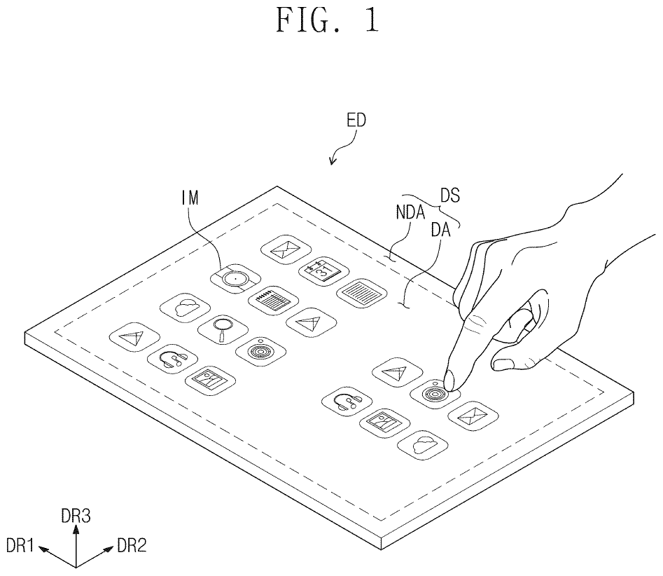

FIG. 1 is a perspective view of an electronic device according to one or more embodiments of the present disclosure.

Referring to FIG. 1, an electronic device ED according to one or more embodiments of the present disclosure may have a rectangular shape having long sides extending in a first direction DR1 and short sides extending in a second direction DR2 intersecting the first direction DR1. However, the present disclosure is not limited thereto, and the electronic device ED may have various shapes such as a circular shape or a polygonal shape.

Hereinafter, a direction substantially perpendicular to a plane defined by the first direction DR1 and the second direction DR2 is defined as a third direction DR3. In the specification, the expression “when viewed on a plane” is defined as a state of being viewed from the third direction DR3.

An upper surface of the electronic device ED may be defined as a display surface DS and may have a plane defined by the first direction DR1 and the second direction DR2. Images IM generated by the electronic device ED may be provided to a user through the display surface DS.

The display surface DS may include a display area DA and a non-display area NDA around the display area DA. The display area DA displays an image, and the non-display area NDA does not display the image. The non-display area NDA may be around (e.g., may surround) the display area DA and may define an edge of the electronic device ED printed in a suitable color (e.g., a predetermined color).

The electronic device ED may be a large-sized electronic device, such as, televisions, monitors, and/or external billboards. Further, the electronic device ED may be one of small and medium-sized electronic devices, such as, personal computers, laptop computers, personal digital terminals, vehicle navigation systems, game consoles, smartphones, tablets, and/or cameras. However, these are presented merely as examples, and the electronic device ED may also be applied to other electronic devices without departing from the spirit and scope of the present disclosure.

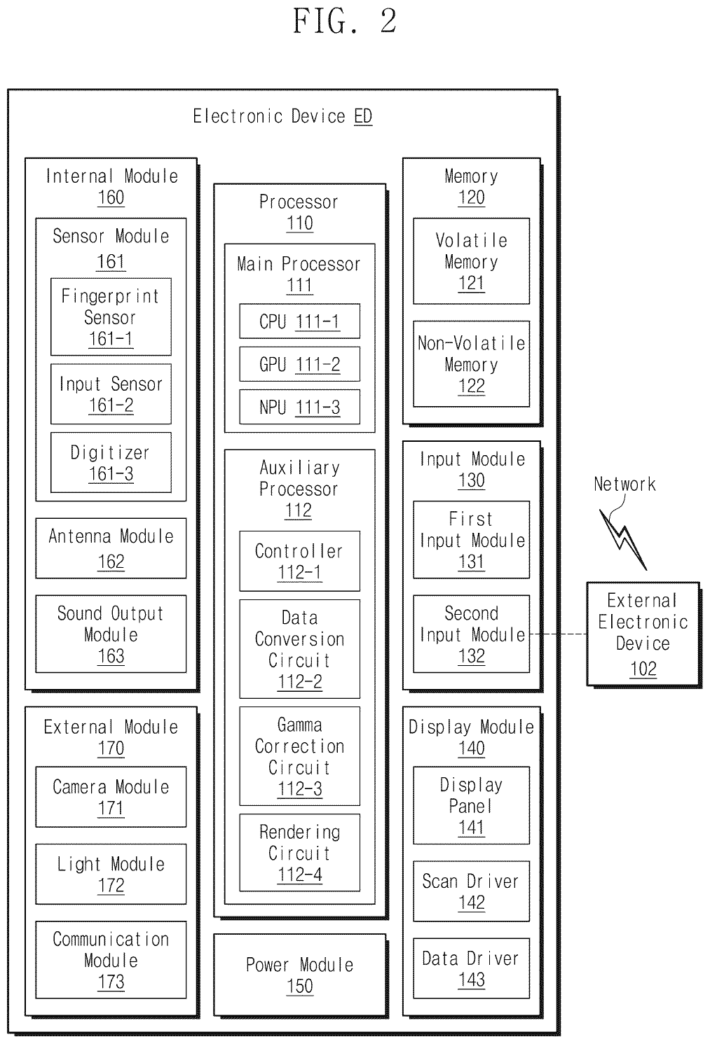

FIG. 2 is a block diagram of the electronic device according to one or more embodiments of the present disclosure.

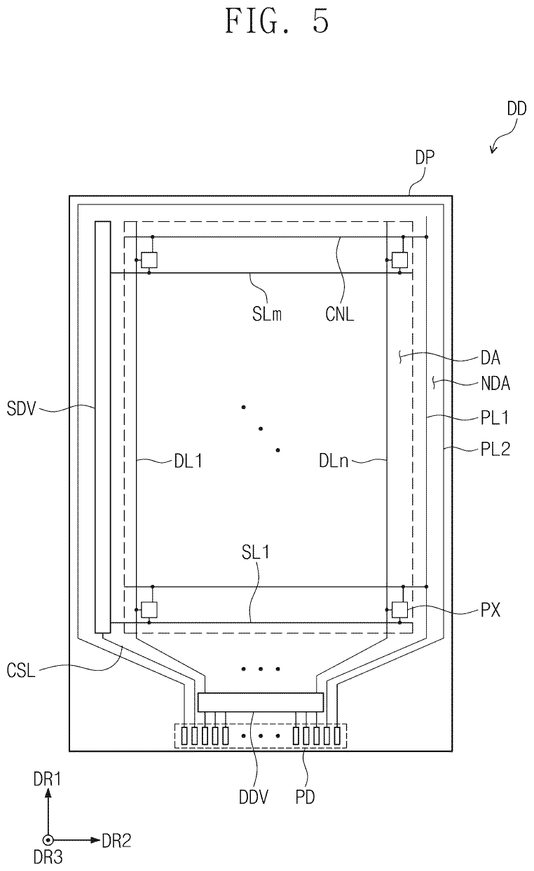

Referring to FIG. 2, the electronic device ED may output a variety of information through a display device DD (e.g., see FIG. 5) or a display module 140 in an operating system. When a processor 110 executes an application stored in a memory 120, the display device DD (e.g., see FIG. 5) or the display module 140 may provide application information to a user through a display panel DP (e.g., see FIG. 5) or the display panel 141 in FIG. 2.

The processor 110 obtains an external input through an input module 130 or a sensor module 161 and executes an application corresponding to the external input. For example, when the user selects a camera icon displayed in the display panel 141, the processor 110 obtains a user input through an input sensor 161-2 and activates a camera module 171. The processor 110 transfers image data corresponding to a photographed image obtained through the camera module 171 to the display module 140. The display module 140 may display an image corresponding to the photographed image through the display panel 141.

As another example, when authentication for personal information is performed in the display module 140, a fingerprint sensor 161-1 obtains input fingerprint information as input data. The processor 110 compares the input data obtained through the fingerprint sensor 161-1 and authentication data stored in the memory 120 and executes an application depending on the comparison result. The display module 140 may display information executed depending on logic of the application, through the display panel 141.

As another example, when the user selects a music streaming icon displayed in the display module 140, the processor 110 obtains the user input through the input sensor 161-2 and activates a music streaming application stored in the memory 120. When a music play command is input to the music streaming application, the processor 110 activates a sound output module 163 and provides the user with sound information corresponding to the music play command.

Hereinabove, the operation of the electronic device ED is briefly described. Hereinbelow, a configuration of the electronic device ED will be described in detail. Some of components of the electronic device ED to be described later may be integrally implemented with one component, and the one component may be divided into two or more components.

The electronic device ED may communicate with an external electronic

device 102 through a network (e.g., a short-range wireless communication network or a long-range wireless communication network). According to one or more embodiments, the electronic device ED may include the processor 110, the memory 120, the input module 130, the display module 140, a power module 150, an internal module 160, and an external module 170. According to one or more embodiments, the electronic device ED may not include at least one of the above components or may further include one or more other components. According to one or more embodiments, some of the above components (e.g., the sensor module 161, an antenna module 162, or the sound output module 163) may be integrated into another component (e.g., the display module 140).

The processor 110 may execute software to control at least one component (e.g., a hardware or software component) of the electronic device ED connected with the processor 110 and may perform various data processing or operations. According to one or more embodiments, as at least a part of the data processing or operations, the processor 110 may store a command or data received from another component (e.g., the input module 130, the sensor module 161, or a communication module 173) in a volatile memory 121, may process the command or data stored in the volatile memory 121, and may store the processed data in a nonvolatile memory 122.

The processor 110 may include a main processor 111 and an auxiliary processor 112. The main processor 111 may include one or more of a central processing unit (CPU) 111-1 or an application processor (AP). The main processor 111 may further include one or more of a graphic processing unit (GPU) 111-2, a communication processor (CP), and an image signal processor (ISP).

The main processor 111 may further include a neural processing unit (NPU) 111-3. The NPU 111-3 may be a processor specialized for processing of an artificial intelligence model, and the artificial intelligence model may be created through machine learning. The artificial intelligence model may include a plurality of artificial neural network (ANN) layers.

The artificial neural network may include one of a deep neural network (DNN), a convolutional neural network (CNN), a recurrent neural network (RNN), a restricted Boltzmann machine (RBM), a deep belief network (DBN), a bidirectional recurrent deep neural network (BRDNN), a deep Q-network, or a combination of two or more thereof, but the present disclosure is not limited thereto.

Additionally or alternatively, the artificial intelligence model may include a software structure in addition to a hardware structure. At least two of the above processing units and processors may be integrally implemented into one component (e.g., a single chip), or each of the above processing units and processors may be implemented with an independent component (e.g., a plurality of chips).

The auxiliary processor 112 may include a controller 112-1. The controller 112-1 may include an interface conversion circuit and a timing control circuit. The controller 112-1 receives an image signal from the main processor 111 and outputs the image data obtained by converting a data format of the image signal so as to be suitable for the specification of an interface with the display device DD. The controller 112-1 may output various kinds of control signals necessary to drive the display device DD.

The auxiliary processor 112 may further include a data conversion circuit 112-2, a gamma correction circuit 112-3, a rendering circuit 112-4, etc. The data conversion circuit 112-2 may receive the image data from the controller 112-1, may compensate for the image data such that an image having a desired luminance is displayed depending on characteristics of the electronic device ED or user settings, or may convert the image data to reduce power consumption or to compensate for afterimages.

The gamma correction circuit 112-3 may convert the image data or a gamma reference voltage such that an image displayed on the electronic device ED has a desired gamma characteristic.

The rendering circuit 112-4 may receive the image data from the controller 112-1 and may render the image data in consideration of pixel arrangement of the display module 140 applied to the electronic device ED.

At least one of the data conversion circuit 112-2, the gamma correction circuit 112-3, or the rendering circuit 112-4 may be integrated into any other component (e.g., the main processor 111 or the controller 112-1). At least one of the data conversion circuit 112-2, the gamma correction circuit 112-3, or the rendering circuit 112-4 may be integrated into a data driver 143 (or DDV of FIG. 5) to be described later.

The memory 120 may store various data used by at least one component (e.g., the processor 110 or the sensor module 161) of the electronic device ED and input data or output data for a command related thereto. The memory 120 may include at least one of the volatile memory 121 or the non-volatile memory 122.

The input module 130 may receive the command or data to be used by a component (e.g., the processor 110, the sensor module 161, or the sound output module 163) of the electronic device ED from the outside of the electronic device ED (e.g., the user or the external electronic device 102).

The input module 130 may include a first input module 131 through which the command or data is input from the user and a second input module 132 through which the command or data is input from the external electronic device 102. The first input module 131 may include a microphone, a mouse, a keyboard, a key (e.g., a button), and/or a pen (e.g., a passive pen or an active pen).

The second input module 132 may support a specified protocol capable of being connected to the external electronic device 102 by wire or wirelessly. According to one or more embodiments, the second input module 132 may include a high definition multimedia interface (HDMI), a universal serial bus (USB) interface, a secure digital (SD) card interface, and/or an audio interface. The second input module 132 may include a connector capable of being physically connected with the external electronic device 102, for example, an HDMI connector, a USB connector, an SD card connector, and/or an audio connector (e.g., a headphone connector).

The display module 140 visually provides information to the user. As illustrated in FIG. 2 (and FIG. 5), the display module 140 (or the display device DD) may include the display panel 141 (or DP of FIG. 5), a scan driver 142 (or SDV of FIG. 5), and the data driver 143 (or DDV of FIG. 5). The display module 140 (or display device DD of FIG. 5) may further include a window, a chassis, and a bracket for protecting the display panel 141 (or DP of FIG. 5).

The display panel 141 (or DP of FIG. 5) may include a liquid crystal display panel, an organic light emitting display panel, or an inorganic light emitting display panel, and the type of the display panel DP is not particularly limited. The display panel 141 (or DP of FIG. 5) may be of a rigid type or a flexible type that may be rolled and/or folded. The display module 140 (or the display device DD of FIG. 5) may further include a supporter, a bracket, or a heat dissipating member supporting the display panel DP.

The display module 140 (or the display device DD of FIG. 5) may further include a voltage generating circuit. The voltage generating circuit may output various voltages required for driving the display panel 141 (or DP of FIG. 5).

The power module 150 supplies power to the components of the electronic device ED. The power module 150 may include a battery that charges a power supply voltage. The battery may include a primary cell that may not be recharged, a secondary cell that is rechargeable, and/or a fuel cell. The power module 150 may include a power management integrated circuit (PMIC). The PMIC supplies suitable power (e.g., optimized power) to each of the display module 140 (or the display device DD of FIG. 5) and the other modules. The power module 150 may include a wireless power transmission and/or reception member electrically connected with the battery. The wireless power transmission and/or reception member may include a plurality of antenna radiators that are in the form of a coil.

The electronic device ED may further include the internal module 160 and the external module 170. The internal module 160 may include the sensor module 161, the antenna module 162, and the sound output module 163. The external module 170 may include the camera module 171, a light module 172, and the communication module 173.

The sensor module 161 may sense an input by a user's body or an input by a pen from among the first input module 131 and may generate an electrical signal or a data value corresponding to the input. The sensor module 161 may include at least one of the fingerprint sensor 161-1, the input sensor 161-2, and a digitizer 161-3.

The fingerprint sensor 161-1 may generate a data value corresponding to the user's fingerprint. The fingerprint sensor 161-1 may include one of an optical fingerprint sensor or a capacitive fingerprint sensor.

The input sensor 161-2 may generate a data value corresponding to coordinate information of the input by the user's body and/or the input by the pen. The input sensor 161-2 generates a capacitance change due to the input as a data value. The input sensor 161-2 may sense the input by the passive pen and/or may exchange data with the active pen.

The input sensor 161-2 may measure a biometric signal such as blood pressure, moisture, and/or body fat. For example, when the user touches his/her body part to a sensor layer or a sensing panel and does not move during a given time period, the input sensor 161-2 may sense the biometric signal based on a change in an electric field caused by the body part and may output the information desired by the user to the display device DD.

The digitizer 161-3 may generate a data value corresponding to the coordinate information of the input by the pen. The digitizer 161-3 generates the amount of electromagnetic change by the input as a data value. The digitizer 161-3 may sense the input by the passive pen and/or may exchange data with the active pen.

At least one of the fingerprint sensor 161-1, the input sensor 161-2, or the digitizer 161-3 may be implemented as a sensor layer formed on the display panel 141 (or DP of FIG. 5) through a continuous process. The fingerprint sensor 161-1, the input sensor 161-2, and the digitizer 161-3 may be arranged above the display panel DP, and one of the fingerprint sensor 161-1, the input sensor 161-2, or the digitizer 161-3, e.g., the digitizer 161-3, may be disposed below the display panel DP.

At least two of the fingerprint sensor 161-1, the input sensor 161-2, and the digitizer 161-3 may be formed integrally with one sensing panel through the same process. When the fingerprint sensor 161-1, the input sensor 161-2, and the digitizer 161-3 are formed integrally with the one sensing panel, the sensing panel may be disposed between the display panel 141 (or DP of FIG. 5) and the window disposed above the display panel 141 (or DP of FIG. 5). According to one or more embodiments, the sensing panel may be disposed on the window, and a location of the sensing panel is not particularly limited.

At least one of the fingerprint sensor 161-1, the input sensor 161-2, or the digitizer 161-3 may be embedded in the display panel 141 (or DP of FIG. 5). That is, at least one of the fingerprint sensor 161-1, the input sensor 161-2, or the digitizer 161-3 may be concurrently (e.g., simultaneously) formed through a process of forming elements (e.g., a light emitting element, a transistor, etc.) included in the display module 140 (or the display panel DP of FIG. 5).

In addition, the sensor module 161 may generate an electrical signal and/or a data value corresponding to an internal state or an external state of the electronic device ED. The sensor module 161 may further include, for example, a gesture sensor, a gyro sensor, a barometric pressure sensor, a magnetic sensor, an acceleration sensor, a grip sensor, a proximity sensor, a color sensor, an infrared (IR) sensor, a biometric sensor, a temperature sensor, a humidity sensor, and/or an illuminance sensor.

The antenna module 162 may include one or more antennas for transmitting and/or receiving a signal or power to and/or from an external source. According to one or more embodiments, through an antenna suitable for a communication method, the communication module 173 may transmit a signal to an external electronic device or may receive a signal from the external electronic device. An antenna pattern of the antenna module 162 may be integrated with one component (e.g., the display panel 141 (or DP of FIG. 5)) of the display module 140 (or the display device DD of FIG. 5) or the input sensor 161-2.

The sound output module 163, which is a device for outputting a sound signal to the outside of the electronic device ED, may include, for example, a speaker used for general purposes such as multimedia playback and/or recording playback and a receiver used exclusively for receiving calls. According to one or more embodiments, the receiver and the speaker may be either integrally or separately implemented. A sound output pattern of the sound output module 163 may be integrated with the display module 140 (or the display device DD of FIG. 5).

The camera module 171 may capture a still image and/or a moving image. According to one or more embodiments, the camera module 171 may include one or more lenses, an image sensor, and/or an image signal processor. The camera module 171 may further include an infrared camera capable of measuring the presence or absence of the user, the location of the user, and/or the line of sight of the user.

The light module 172 may provide a light. The light module 172 may include a light emitting diode and/or a xenon lamp. The light module 172 may operate in conjunction with the camera module 171 or may operate independently.

The communication module 173 may establish a wired or wireless communication channel between the electronic device ED and the external electronic device 102 and may support communication execution through the established communication channel. The communication module 173 may include one of a wireless communication module, such as a cellular communication module, a short- range wireless communication module, or a global navigation satellite system (GNSS) communication module, and/or a wired communication module, such as a local area network (LAN) communication module and/or a power line communication module or may include all thereof.

The communication module 173 may communicate with the external electronic device 102 over a short-range communication network such as Bluetooth, Wi-Fi direct, and/or infrared data association (IrDA), or a long-range communication network such as a cellular network, an Internet, and/or a computer network (e.g., a LAN or WAN). The various kinds of communication modules 173 may be implemented as one chip or separate chips.

The input module 130, the sensor module 161, the camera module 171, etc. may be used to control an operation of the display module 140 (or the display device DD of FIG. 5) in conjunction with the processor 110.

The processor 110 outputs the command and/or data to the display module 140 (or the display device DD of FIG. 5), the sound output module 163, the camera module 171, or the light module 172 based on the input data received from the input module 130. For example, the processor 110 may generate the image data corresponding to the input data applied through the mouse and/or the active pen to output the image data to the display module 140 (or the display device DD of FIG. 5) or may generate command data corresponding to the input data to output the command data to the camera module 171 and/or the light module 172.

When the input data is not received from the input module 130 during a given time period, the processor 110 may switch an operating mode of the electronic device ED to a low-power mode or a sleep mode to reduce power consumption of the electronic device ED.

The processor 110 outputs the command and/or data to the display module 140 (or the display device DD of FIG. 5), the sound output module 163, the camera module 171, and/or the light module 172 based on sensing data received from the sensor module 161. For example, the processor 110 may compare authentication data obtained through the fingerprint sensor 161-1 with authentication data stored in the memory 120 and may then execute an application depending on the comparison result.

The processor 110 may execute a command based on the sensing data sensed by the input sensor 161-2 and/or the digitizer 161-3 or may output the image data corresponding to the sensing data to the display module 140 (or the display device DD of FIG. 5). When the sensor module 161 includes a temperature sensor, the processor 110 may receive temperature data associated with a temperature measured from the sensor module 161 and may further perform luminance correction on the image data based on the temperature data.

The processor 110 may receive measurement data about the presence or absence of the user, the location of the user, and/or the line of sight of the user from the camera module 171. The processor 110 may further perform the luminance correction on the image data based on the measurement data. For example, the processor 110 that determines the presence or absence of the user through the input from the camera module 171 may display, to the display module 140 (or the display device DD of FIG. 5), the image data whose luminance is corrected through the data conversion circuit 112-2 and/or the gamma correction circuit 112-3.

Some of the components may be connected to each other through a communication manner between peripheral devices, for example, a bus, a general purpose input/output (GPIO), a serial peripheral interface (SPI), a mobile industry processor interface (MIPI), and/or a ultra path interconnect (UPI) link and may exchange a signal (e.g., the command and/or data) between each other. The processor 110 may communicate with the display device DD through a promised interface. For example, one of the communication methods described above may be used, and the present disclosure is not limited thereto.

The electronic device ED according to one or more embodiments of the present disclosure may be implemented as various types of devices. The electronic device ED may include, for example, at least one of a portable communication device (e.g., a smartphone), a computer device, a portable multimedia device, a portable medical device, a camera, a wearable device, or home appliances. The electronic device ED according to one or more embodiments of the present disclosure is not limited to the above devices.

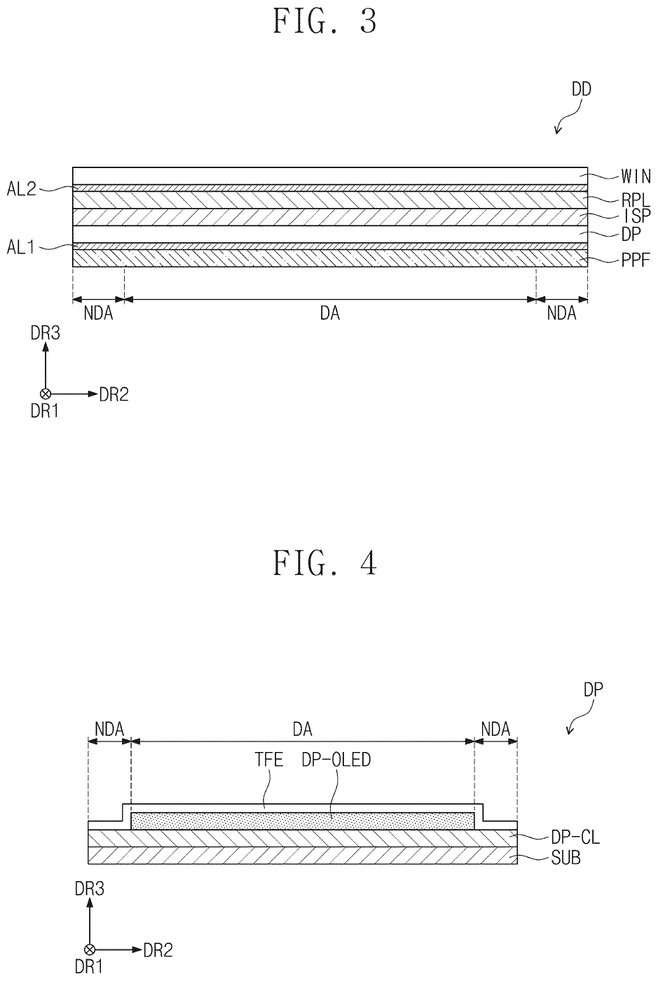

FIG. 3 is a view illustrating, by way of example, a cross section of a display device included in the electronic device illustrated in FIGS. 1 and 2.

By way of example, FIG. 3 is a cross-sectional view of the display device DD when viewed in the first direction DR1.

Referring to FIG. 3, the display device DD may include the display panel DP, an input sensing unit ISP, a reflection preventing layer RPL, a window WIN, a panel protecting film PPF, a first adhesive layer AL1, and a second adhesive layer AL2.

The display panel DP may be a flexible display panel. The display panel DP according to one or more embodiments of the present disclosure may be a light emitting display panel. For example, the display panel DP may be an organic light emitting display panel or an inorganic light emitting display panel. A light emitting layer of the organic light emitting display panel may include an organic light emitting material. A light emitting layer of the inorganic light emitting display panel may include a quantum dot and/or a quantum rod. Hereinafter, the display panel DP will be described as the organic light emitting display panel.

The input sensing unit ISP may be disposed on the display panel DP. The input sensing unit ISP may include a plurality of sensing units for sensing an external input in a capacitive manner. The input sensing unit ISP may be directly manufactured on the display panel DP when the display device DD is manufactured. However, the present disclosure is not limited thereto, and the input sensing unit ISP may be manufactured as a separate panel from the display panel DP and attached to the display panel DP by an adhesive layer.

The reflection preventing layer RPL may be disposed on the input sensing unit ISP. The reflection preventing layer RPL may be directly manufactured on the input sensing unit ISP when the display device DD is manufactured. However, the present disclosure is not limited thereto, and the reflection preventing layer RPL may be manufactured as a separate panel and attached to the input sensing unit ISP by an adhesive layer.

The reflection preventing layer RPL may be defined as an external light reflection preventing film. The reflection preventing layer RPL may reduce a reflectance of an external light input from an upper side of the display device DD toward the display panel DP. The external light may not be visually recognized by the user due to the reflection preventing layer RPL.

When an external light traveling toward the display panel DP is reflected by the display panel DP and provided back to an external user, the user may visually recognize the external light like a mirror. To prevent this phenomenon, by way of example, the reflection preventing layer RPL may include a plurality of color filters that display the same colors as those of the pixels of the display panel DP.

The color filters may filter the external light into the same colors as those of the pixels. In this case, the external light may not be visually recognized by the user. However, the present disclosure is not limited thereto, and the reflection preventing layer RPL may include a phase retarder and/or a polarizer to reduce the reflectance of the external light.

The window WIN may be disposed on the reflection preventing layer RPL. The window WIN may protect the display panel DP, the input sensing unit ISP, and the reflection preventing layer RPL from external scratches and/or impacts.

The panel protecting film PPF may be disposed under the display panel DP. The panel protecting film PPF may protect a lower portion of the display panel DP. The panel protecting film PPF may include a flexible plastic material such as polyethyleneterephthalate (PET).

The first adhesive layer AL1 may be disposed between the display panel DP and the panel protecting film PPF, and the display panel DP and the panel protecting film PPF may adhere to each other by the first adhesive layer AL1. The second adhesive layer AL2 may be disposed between the window WIN and the reflection preventing layer RPL, and the window WIN and the reflection preventing layer RPL may adhere to each other by the second adhesive layer AL2.

FIG. 4 is a view illustrating, by way of example, a cross section of a display panel illustrated in FIG. 3.

By way of example, FIG. 4 illustrates a cross section of the display panel DP when viewed in the first direction DR1.

Referring to FIG. 4, the display panel DP may include a base layer SUB, a circuit element layer DP-CL disposed on the base layer SUB, a display element layer DP-OLED disposed on the circuit element layer DP-CL, and a thin film encapsulation layer TFE disposed on the display element layer DP-OLED.

The base layer SUB may include the display area DA and the non-display area NDA around the display area DA. The base layer SUB may include glass and/or a flexible plastic material such as polyimide (PI). The display element layer DP-OLED may be disposed in the display area DA.

A plurality of pixels may be arranged in the circuit element layer DP-CL and the display element layer DP-OLED. Each of the pixels may include a transistor disposed on the circuit element layer DP-CL and a light emitting element disposed on the display element layer DP-OLED and connected to the transistor.

The thin film encapsulation layer TFE may be disposed on the circuit element layer DP-CL to cover the display element layer DP-OLED. The thin film encapsulation layer TFE may protect the pixels from moisture, oxygen, and/or external foreign substances.

FIG. 5 is a plan view of the display device illustrated in FIG. 3.

Referring to FIG. 5, the display device DD may include the display panel DP, the scan driver SDV, the data driver DDV, and a plurality of pads PD.

The display panel DP may have a rectangular shape having long sides extending in the first direction DR1 and short sides extending in the second direction DR2, but the shape of the display panel DP is not limited thereto. The display panel DP may include the display area DA and the non-display area NDA around (e.g., surrounding) the display area DA.

The display panel DP may include a plurality of pixels PX, a plurality of scan lines SL1 to SLm, a plurality of data lines DL1 to DLn, a control line CSL, a first power line PL1, a second power line PL2, and connection lines CNL. “m” and “n” are natural numbers.

The pixels PX may be arranged in the display area DA. The pixels PX may be arranged in a matrix form (e.g., the pixels PX may be arranged along rows and columns of a matrix), but the arrangement of the pixels PX is not limited thereto.

The scan driver SDV may be disposed in the non-display area NDA adjacent to one of the long sides of the display panel DP. When viewed on a plane (e.g., in a plan view), the scan driver SDV may be adjacent to a left side of the display panel DP.

The data driver DDV may be disposed in the non-display area NDA that is adjacent to one of the short sides of the display panel DP. When viewed on a plane (e.g., in a plan view), the data driver DDV may be adjacent to a lower end of the display panel DP.

The scan lines SL1 to SLm may extend in the second direction DR2 and may be connected to the pixels PX and the scan driver SDV. The data lines DL1 to DLn may extend in the first direction DR1 and may be connected to the pixels PX and the data driver DDV.

The first power line PL1 may extend in the first direction DR1 and may be disposed in the non-display area NDA. The first power line PL1 may be adjacent to the long side of the display panel DP on which the scan driver SDV is not disposed.

The connection lines CNL may extend in the second direction DR2, may be arranged along the first direction DR1, and may be connected to the first power line PL1 and the pixels PX. A first voltage may be applied to the pixels PX through the first power line PL1 and the connection lines CNL connected to each other.

The second power line PL2 may be disposed in the non-display area NDA and may extend along the long sides of the display panel DP and the other one short side of the display panel DP on which the data driver DDV is not disposed. The second power line PL2 may be disposed outside the scan driver SDV.

In one or more embodiments, the second power line PL2 may extend toward the display area DA and may be connected to the pixels PX. A second voltage may be applied to the pixels PX through the second power line PL2.

The control line CSL may be connected to the scan driver SDV and may extend toward the lower end of the display panel DP. A control signal for controlling an operation of the scan driver SDV may be provided to the scan driver SDV through the control line CSL.

The pads PD may be arranged in the non-display area NDA adjacent to the lower end of the display panel DP and may be closer to the lower end of the display panel DP than the data driver DDV. The data driver DDV, the first power line PL1, the second power line PL2, and the control line CSL may be connected to the pads PD. The data lines DL1 to DLn may be connected to the data driver DDV, and the data driver DDV may be connected to the pads PD corresponding to the data lines DL1 to DLn.

In one or more embodiments, the display device DD may further include a timing controller for controlling operations of the scan driver SDV and the data driver DDV and a voltage generator for generating the first voltage and the second voltage. The timing controller and the voltage generator may be mounted on a printed circuit board (PCB) and connected to the pads PD through the printed circuit board (PCB).

The scan driver SDV may generate a plurality of scan signals, and the scan signals may be applied to the pixels PX through the scan lines SL1 to SLm. The data driver DDV may generate a plurality of data voltages, and the data voltages may be applied to the pixels PX through the data lines DL1 to DLn.

The pixels PX may receive the data voltages in response to the scan signals. The pixels PX may display an image by emitting lights having luminance corresponding to the data voltages.

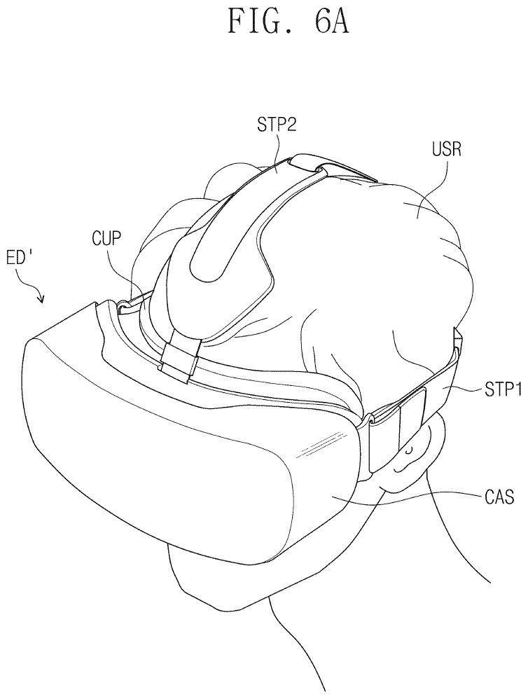

FIG. 6A is a view illustrating an electronic device according to one or more embodiments of the present disclosure.

Referring to FIG. 6A, an electronic device ED′ according to one or more embodiments of the present disclosure may be defined as a head mounted display device. The electronic device ED′ may be worn on the head of a user USR.

The electronic device ED′ may block a peripheral view of the user USR and provide an image to the user USR. The electronic device ED′ may provide a virtual reality to the user USR.

The electronic device ED′ may include a case CAS, a cushion part CUP, and strap parts STP1 and STP2. The case CAS may be worn on the user USR. The display panel DP that displays an image, an acceleration sensor, and/or the like may be accommodated in the case CAS. The display panel DP may be the display panel DP illustrated in FIG. 5.

The acceleration sensor may sense movement of the user USR and transmit a suitable signal (e.g., a predetermined signal) to the display panel DP. Thus, the display panel DP may provide an image corresponding to a change in the line of sight of the user USR. As a result, the user USR may experience the virtual reality similar to a reality.

The cushion part CUP may be disposed between the case CAS and the user USR. The cushion part CUP may include a material that is freely deformable. For example, the cushion part CUP may include a polymer resin (e.g., polyurethane, polycarbonate, polypropylene, and/or polyethylene). Further, the cushion part CUP may include a sponge formed by foaming a rubber liquid, a urethane-based material, and/or an acryl-based material.

The cushion part CUP may allow the case CAS to be in close contact with the user USR, thereby improving wearability of the user USR. The cushion part CUP may be detached from the case CAS.

The strap parts STP1 and STP2 may be coupled to the case CAS so that the case CAS may be easily worn on the user USR. The strap parts STP1 and STP2 may include the first strap STP1 and the second strap STP2.

The first strap STP1 may be worn along a periphery (e.g., circumference) of the head of the user USR. The first strap STP1 may fix the case CAS to the user USR so that the case CAS may be in close contact with the head of the user USR.

The second strap STP2 may connect the case CAS and the first strap STP1 along an upper portion of the head of the user USR. The second strap STP2 may prevent the case CAS from slipping down.

FIG. 6B is an exploded perspective view of the electronic device illustrated in FIG. 6A.

Referring to FIG. 6B, the case CAS may include a first case CAS1 and a second case CAS2. The first case CAS1 and the second case CAS2 may be separated from each other.

The display panel DP may be disposed between the first case CAS1 and the second case CAS2. The first case CAS1 and the second case CAS2 may be coupled so that the display panel DP may be accommodated in the case CAS. By way of example, the display panel DP may provide a left-eye image and a right-eye image to the user USR. Thus, the display panel DP may provide a stereoscopic image to the user USR.

An optical system OTP may be disposed in (e.g., inside) the first case CAS1. The optical system OTP may enlarge an image provided from the display panel DP.

The optical system OTP may be disposed between the display panel DP and eyes of the user USR. The optical system OTP may include a left-eye optical system OTP1 and a right-eye optical system OTP2. The left-eye optical system OTP1 may provide an enlarged image to a left eye of the user USR, and the right-eye optical system OTP2 may provide an enlarged image to a right eye of the user USR.

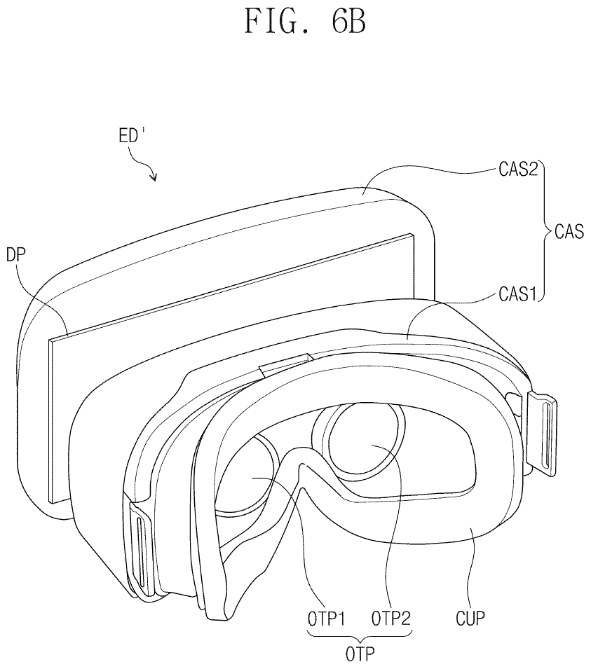

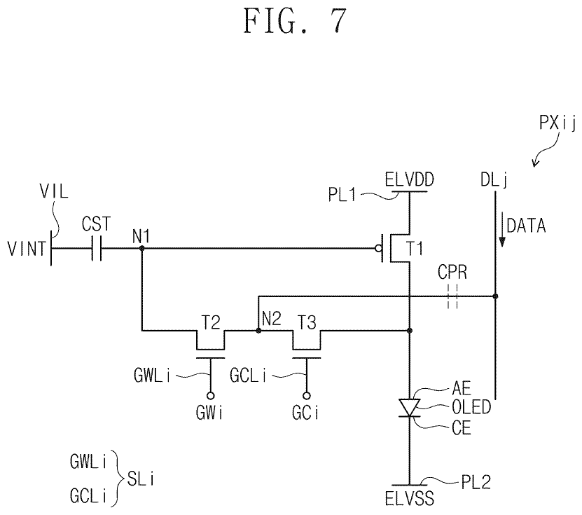

FIG. 7 illustrates an equivalent circuit of one of the pixels illustrated in FIG. 5.

By way of example, FIG. 7 illustrates a pixel PXij connected to the i^{th} scan line SLi and the j^{th} data line DLj. “i” and “j” are natural numbers. Hereinafter, for convenience of description, the wording “i^{th}” and “j^{th}” will be omitted.

Referring to FIG. 7, the pixel PXij may include a first transistor T1, a second transistor T2, a third transistor T3, a light emitting element OLED, and a capacitor CST.

The scan line SLi may include a write scan line GWLi and a compensation scan line GCLi. The write scan line GWLi may receive a write scan signal GWi, and the compensation scan line GCLi may receive a compensation scan signal GCi.

A parasitic capacitor CPR may be unintentionally formed between a second node N2 between the second transistor T2 and the third transistor T3 and the data line DLj. However, the parasitic capacitor CPR is not a component of the pixel PXij, and thus description of the parasitic capacitor CPR is omitted when an operation of the pixel PXij is described.

The light emitting element OLED may be defined as an organic light emitting element. The light emitting element OLED may include an anode AE and a cathode CE. The anode AE may be connected to the first power line PL1 through the first transistor T1. The cathode CE may be connected to the second power line PL2. The first power line PL1 may receive a first voltage ELVDD. The second power line PL2 may receive a second voltage ELVSS having a lower level than that of the first voltage ELVDD.

The first transistor T1 may be a p-channel metal-oxide semiconductor (PMOS) transistor. The second transistor T2 and the third transistor T3 may be n-type metal oxide semiconductor (NMOS) transistors. The first transistor T1 may include a silicon semiconductor, and the second transistor T2 and the third transistor may include an oxide semiconductor.

Each of the first transistor T1, the second transistor T2, and the third transistor T3 may include a source electrode, a drain electrode, and a gate electrode.

Hereinafter, in FIG. 7, for convenience, one of the source electrode and the drain electrode is defined as a first electrode, and the other thereof is defined as a second electrode. Further, the gate electrode is defined as a control electrode.

The first transistor T1 may be defined as a driving transistor, and the second transistor T2 may be defined as a switching transistor. The third transistor T3 may be defined as a compensation transistor.

The first transistor T1 may be connected to the first power line PL1 and the anode AE of the light emitting element OLED and may be switched according to a voltage of a first node N1. The first transistor T1 may include a first electrode connected to the first power line PL1, a second electrode connected to the anode AE of the light emitting element OLED, and a control electrode connected to the first node N1. The first transistor T1 may be turned on by a voltage of the first node N1. The first node N1 may be substantially defined as a control electrode of the first transistor T1.

The second transistor T2 may be connected to the first node N1 and the second node N2. In detail, the second transistor T2 may be connected to the gate electrode of the first transistor T1 and the data line DLj. The second transistor T2 may be switched by the write scan signal GWi.

The second transistor T2 may include a first electrode connected to the first node N1, a second electrode connected to the second node N2, and a control electrode connected to the write scan line GWLi. The second transistor T2 may be turned on by the write scan signal GWi applied through the write scan line GWLi. The third transistor T3 may be connected to the second node N2 and the

anode AE of the light emitting element OLED and may be switched by the compensation scan signal GCi. The third transistor T3 may include a first electrode connected to the second node N2, a second electrode connected to the anode AE of the light emitting element OLED, and a control electrode connected to the compensation scan line GCLi. The third transistor T3 may be turned on by the compensation scan signal GCi applied through the compensation scan line GCLi.

The data line DLj may be connected to the second node N2. Thus, the data line DLj may be connected to the second electrode of the second transistor T2 and the first electrode of the third transistor T3. The data line DLj may receive a data signal DATA.

The anode AE of the light emitting element OLED may be connected to the first power line PL1 through the first transistor T1, and the cathode CE of the light emitting element OLED may be connected to the second power line PL2.

The capacitor CST may include a first electrode connected to an initialization line VIL and a second electrode connected to the first node N1. The initialization line VIL may receive an initialization voltage VINT.

The write scan signal GWi applied to the control electrode of the second transistor T2 may be a global clock signal for concurrent (e.g., simultaneous) light emitting driving. For example, when the display device DD operates in a concurrent (e.g., simultaneous) light emitting driving method, the write scan signal GWi, which is a global clock signal, may be commonly applied to the pixels PX.

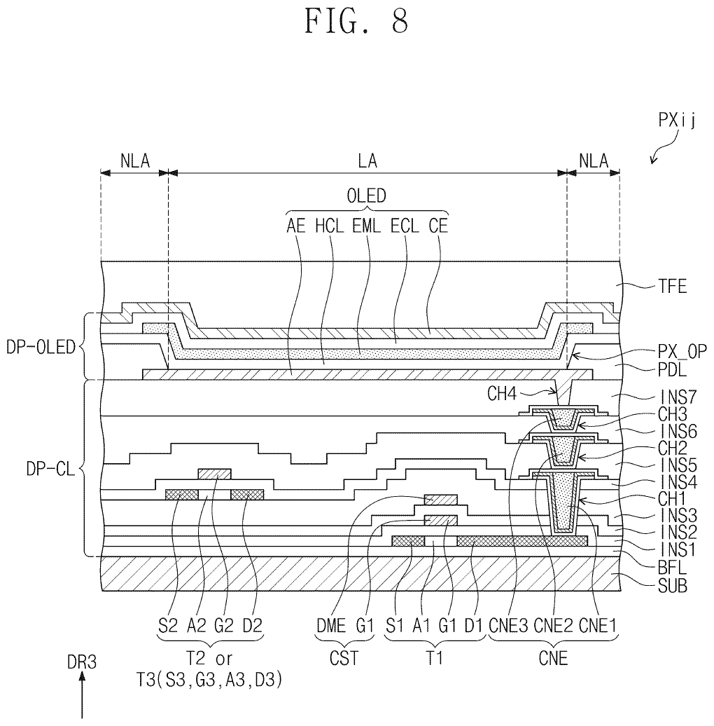

FIG. 8 is a cross-sectional view of one of the pixels illustrated in FIG. 7. FIG. 8 is a schematic cross-sectional view illustrating the light emitting element OLED, the first transistor T1, and the second transistor T2 of the one pixel illustrated in FIG. 7.

Referring to FIG. 8, the light emitting element OLED may include a first electrode AE, a second electrode CE, a hole control layer HCL, an electron control layer ECL, and a light emitting layer EML. The first electrode AE may be the anode AE illustrated in FIG. 7, and the second electrode CE may be the cathode CE illustrated in FIG. 7. The second electrode CE may be disposed above the first electrode AE, and the hole control layer HCL, the electron control layer ECL, and the light emitting layer EML may be arranged between the first electrode AE and the second electrode CE.

The first transistor T1, the second transistor T2, and the light emitting element OLED may be arranged on the base layer SUB. The second transistor T2 may be disposed on the first transistor T1, and the light emitting element OLED may be disposed on the second transistor T2. Thus, the second transistor T2 may be disposed on a layer between the first transistor T1 and the light emitting element OLED.

The display area DA may include a light emitting area LA corresponding to the pixel PXij and a non-light emitting area NLA adjacent to the light emitting area LA. The light emitting element OLED may be disposed in the light emitting area LA.

A buffer layer BFL may be disposed on the base layer SUB. First semiconductor layers S1, A1, and D1 of the first transistor T1 may be arranged on the buffer layer BFL. The first semiconductor layers S1, A1, and D1 may include polysilicon. However, the present disclosure is not limited thereto, and the first semiconductor layers S1, A1, and D1 may include amorphous silicon.

The first semiconductor layers S1, A1, and D1 may include the first source area S1, the first channel area A1, and the first drain area D1. The first channel area A1 may be disposed between the first source area S1 and the first drain area D1. The first source area S1 may correspond to the first electrode of the first transistor T1. The first drain area D1 may correspond to the second electrode of the first transistor T1.

The first source area S1 and the first drain area D1 may have conductivity through a doping process and may substantially serve as a source electrode and a drain electrode of the first transistor T1. The first channel area A1 may substantially correspond to an active area of the first transistor T1.

A first insulating layer INS1 may be disposed on the buffer layer BFL to cover the first semiconductor layers S1, A1, and D1. A first gate electrode G1 of the first transistor T1 may be disposed on the first insulating layer INS1. On a plane, the first gate electrode G1 may overlap the first channel area A1 (e.g., the first gate electrode G1 may overlap the first channel area A1 in a third direction DR3, which is a thickness direction of the base layer SUB). The first gate electrode G1, which is a control electrode of the first transistor T1, may be connected to the first node N1.

Substantially, the first gate electrode G1 may serve as the first node N1. A second insulating layer INS2 may be disposed on the first insulating layer INS1 to cover the first gate electrode G1. A dummy electrode DME may be disposed on the second insulating layer INS2. The dummy electrode DME may form the capacitor CST together with the first gate electrode G1. The first gate electrode G1 may define a first electrode of the capacitor CST, and the dummy electrode DME may define a second electrode of the capacitor CST.

A third insulating layer INS3 may be disposed on the second insulating layer INS2 to cover the dummy electrode DME. Second semiconductor layers S2, A2, and D2 of the second transistor T2 may be arranged on the third insulating layer INS3. The second semiconductor layers S2, A2, and D2 may include an oxide semiconductor formed of a metal oxide. The oxide semiconductor may include a crystalline or amorphous oxide semiconductor.

The second semiconductor layers S2, A2, and D2 may include the second source area S2, the second channel area A2, and the second drain area D2. The second channel area A2 may be disposed between the second source area S2 and the second drain area D2. The second source area S2 may correspond to the second electrode of the second transistor T2. The second drain area D2 may correspond to the first electrode of the second transistor T2.

The second source area S2 and the second drain area D2 may have conductivity through a doping process and may substantially serve as a source electrode and a drain electrode of the second transistor T2. The second channel area A2 may substantially correspond to an active area of the second transistor T2.

A fourth insulating layer INS4 may be disposed on the third insulating layer INS3 to cover the second semiconductor layers S2, A2, and D2. A second gate electrode G2 of the second transistor T2 may be disposed on the fourth insulating layer INS4. The second gate electrode G2 may overlap the second channel area A2. A fifth insulating layer INS5 may be disposed on the fourth insulating layer INS4 to cover the second gate electrode G2.

In one or more embodiments, structures of a third source area S3, a third channel area A3, a third drain area D3, and a third gate electrode G3 of the third transistor T3 disposed on (or at) the same layer as the second transistor T2 may be substantially the same as those of the second transistor T2.

The buffer layer BFL and the first to fifth insulating layers INS1 to INS5 may include inorganic layers. By way of example, the buffer layer BFL and the first insulating layer INS1 may include a silicon oxide layer, and the second insulating layer INS2 may include a silicon nitride layer. The third insulating layer INS3 may include a plurality of inorganic insulating layers that include different materials and are laminated on each other. For example, the third insulating layer INS3 may include a silicon nitride layer and a silicon oxide layer laminated on each other.

The fourth insulating layer INS4 may include a silicon oxide layer. The fifth insulating layer INS5 may include a plurality of inorganic insulating layers that include different materials and are laminated on each other. For example, the fifth insulating layer INS5 may include a silicon oxide layer and a silicon nitride layer laminated on each other. A thickness of each of the third insulating layer INS3 and the fifth insulating layer INS5 may be greater than a thickness of each of the buffer layer BFL and the first insulating layer INS1, the second insulating layer INS2, and the fourth insulating layer INS4.

A connection electrode CNE is disposed between the first transistor T1 and the light emitting element OLED. The connection electrode CNE electrically connects the first transistor T1 and the light emitting element OLED. The connection electrode CNE includes at least a first connection electrode CNE1 connected to the first transistor T1. The connection electrode CNE may include the first connection electrode CNE1, a second connection electrode CNE2 disposed on the first connection electrode CNE1, and a third connection electrode CNE3 disposed on the second connection electrode CNE2.

The first insulating layer INS1 may be disposed on the first semiconductor layers S1, A1, and D1, and the second insulating layer INS2, the third insulating layer INS3, and the fourth insulating layer INS4 may be arranged on the first gate electrode G1. Thus, the first insulating layer INS1, the second insulating layer INS2, the third insulating layer INS3, and the fourth insulating layer INS4 may be arranged on the first transistor T1. In the specification, the first insulating layer INS1, the second insulating layer INS2, the third insulating layer INS3, and the fourth insulating layer INS4 may be described as a “lower insulating layer.” That is, the “lower insulating layer” may include the first insulating layer INS1, the second insulating layer INS2, the third insulating layer INS3, and the fourth insulating layer INS4.

The first connection electrode CNE1 is disposed on the fourth insulating layer INS4 and is disposed above the first transistor T1. In one or more embodiments, the first connection electrode CNE1 may be disposed on (or at) the same layer as that of the second gate electrode G2 of the second transistor T2. The first connection electrode CNE1 may include the same material as the second gate electrode G2 and may be formed concurrently (e.g., simultaneously) with the second gate electrode G2.

The first connection electrode CNE1 is connected to the first transistor T1 through a first contact hole CH1 defined in the first insulating layer INS1, the second insulating layer INS2, the third insulating layer INS3, and the fourth insulating layer INS4. The first connection electrode CNE1 may be directly connected to the first drain area D1 of the first transistor T1. The fifth insulating layer INS5 may be disposed on the fourth insulating layer INS4 to cover the first connection electrode CNE1.

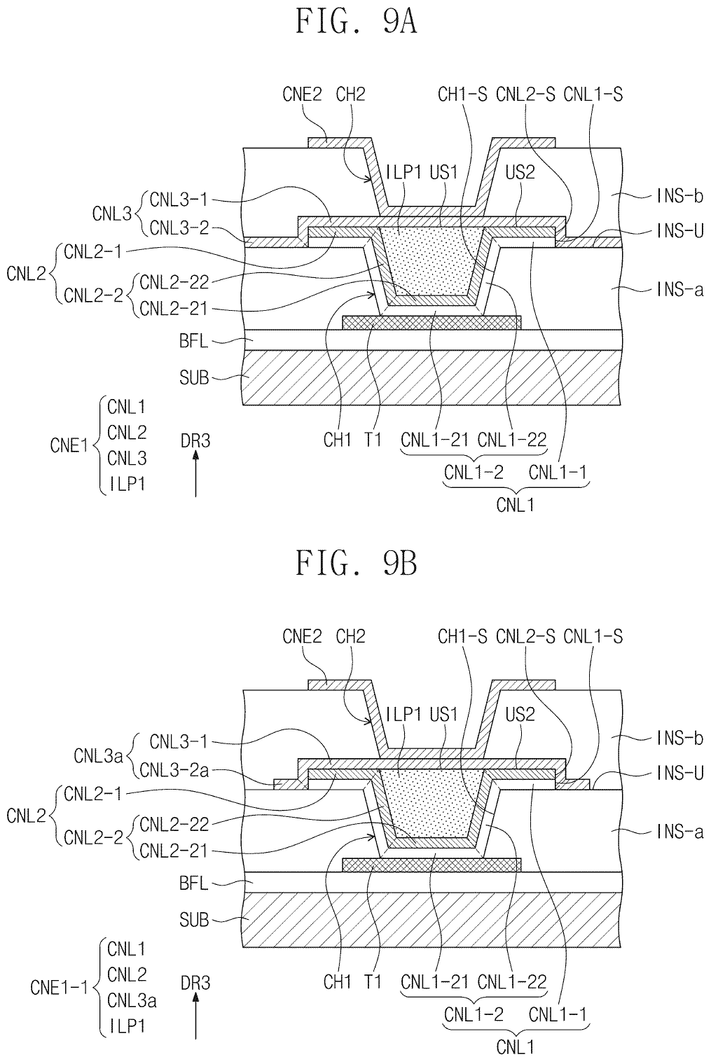

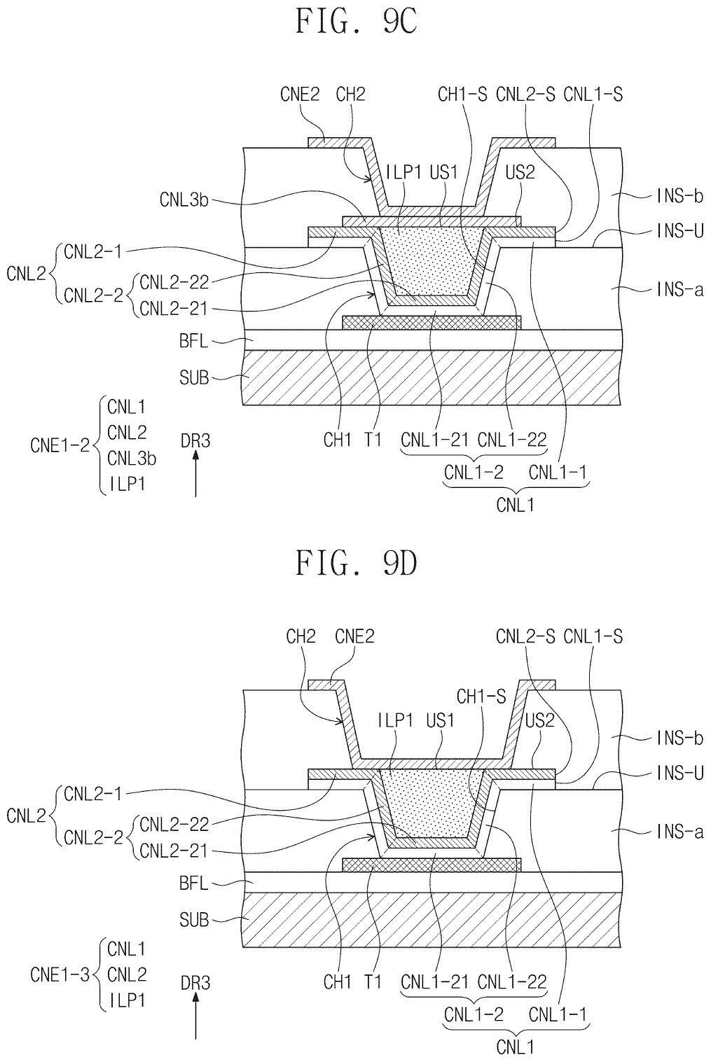

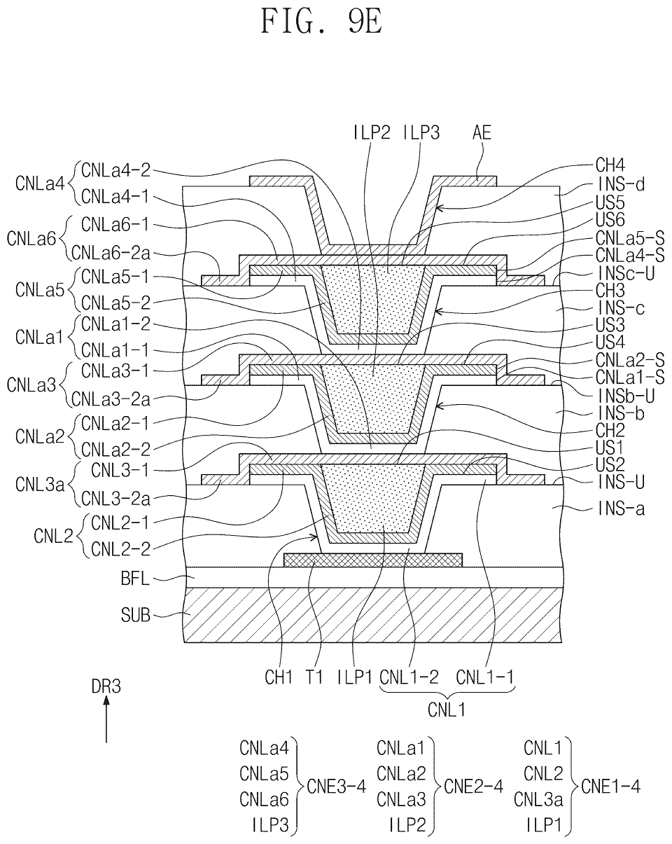

The first connection electrode CNE1 included in the display panel DP according to one or more embodiments includes a plurality of connection layers that are conductive and an insulating pattern disposed between some of the connection layers. A detailed shape of the first connection electrode CNE1 will be described below in description of FIG. 9A and/or the like.

The second connection electrode CNE2 may be disposed on the fifth insulating layer INS5 and may be connected to the first connection electrode CNE1 through a second contact hole CH2 defined in the fifth insulating layer INS5. In the specification, the fifth insulating layer INS5, which covers the first connection electrode CNE1 and in which the second contact hole CH2 is defined, may be described as a “first upper insulating layer.” In the display panel according to one or more embodiments, the second connection electrode CNE2 may include a plurality of connection layers that are conductive as in the first connection electrode CNE1 and an insulating pattern disposed between some of the connection layers.

A sixth insulating layer INS6 may be disposed on the fifth insulating layer INS5 to cover the second connection electrode CNE2.

The third connection electrode CNE3 may be disposed on the sixth insulating layer INS6. The third connection electrode CNE3 may be connected to the second connection electrode CNE2 through a third contact hole CH3 defined in the sixth insulating layer INS6. In the specification, the sixth insulating layer INS6, which covers the second connection electrode CNE2 and in which the third contact hole CH3 is defined, may be described as a “second upper insulating layer.” In the display panel according to one or more embodiments, the third connection electrode CNE3 may include a plurality of connection layers that are conductive as in the first connection electrode and an insulating pattern disposed between some of the connection layers.

A seventh insulating layer INS7 may be disposed on the sixth insulating layer INS6 to cover the third connection electrode CNE3. The sixth insulating layer INS6 and the seventh insulating layer INS7 may include organic layers.

The first electrode AE may be disposed on the seventh insulating layer INS7. Thus, the first electrode AE may be disposed on the first connection electrode CNE1, the second connection electrode CNE2, and the third connection electrode CNE3. The first electrode AE may be connected to the third connection electrode CNE3 through a fourth contact hole CH4 defined in the seventh insulating layer INS7. Thus, the first connection electrode CNE1 may be electrically connected to the first electrode AE through the second connection electrode CNE2 and the third connection electrode CNE3.

A pixel defining film PDL, through which a suitable portion (e.g., a predetermined portion) of the first electrode AE is exposed, may be disposed on the first electrode AE and the seventh insulating layer INS7. An opening PX_OP, through which the suitable portion (e.g., the predetermined portion) of the first electrode AE is exposed, may be defined in the pixel defining film PDL.

The hole control layer HCL may be disposed on the first electrode AE and the pixel defining film PDL. The hole control layer HCL may be commonly disposed in the light emitting area LA and the non-light emitting area NLA. The hole control layer HCL may include a hole transport layer and a hole injection layer.

The light emitting layer EML may be disposed on the hole control layer HCL. The light emitting layer EML may be disposed in an area corresponding to the opening PX_OP. The light emitting layer EML may include an organic material and/or an inorganic material. The light emitting layer EML may generate a light having one of red, green, or blue.

The electron control layer ECL may be disposed on the light emitting layer EML and the hole control layer HCL. The electron control layer ECL may be commonly disposed in the light emitting area LA and the non-light emitting area NLA. The electron control layer ECL may include an electron transport layer and an electron injection layer.

FIG. 8 illustrates, by way of example, that the hole control layer HCL and the electronic control layer ECL are commonly arranged in the light emitting area LA and the non-light emitting area NLA, but the present disclosure is not limited thereto, and at least some of the hole control layer HCL and the electronic control layer ECL may be patterned and disposed in the area corresponding to the opening PX_OP. Further, the light emitting layer EML may be disposed commonly in the light emitting area LA and the non-light emitting area NLA while being not patterned in the area corresponding to the opening PX_OP.

The second electrode CE may be disposed on the electron control layer ECL. The second electrode CE may be commonly disposed in the pixels PX. That is, the second electrode CE may be commonly disposed on the light emitting layers EML of the pixels PX.

Layers from the buffer layer BFL to the seventh insulating layer INS7 may be defined as the circuit element layer DP-CL. A layer, on which the light emitting element OLED is disposed, may be defined as the display element layer DP-OLED.

The thin film encapsulation layer TFE may be disposed on the light emitting element OLED. The thin film encapsulation layer TFE may include an inorganic layer, an organic layer, and an inorganic layer that are sequentially laminated. The inorganic layers may include inorganic materials and may protect the pixels from moisture and/or oxygen. The organic layer may include an organic material and protect the pixels PX from foreign substances such as dust particles.

The first voltage ELVDD may be applied to the first electrode AE, and the second voltage ELVSS may be applied to the second electrode CE. Holes and electrons injected into the light emitting layer EML are combined to each other to form excitons, and as the excitons transition to a ground state, the light emitting element OLED may emit a light. The light emitting element OLED may emit a light to display an image.

FIGS. 9A-9E are enlarged cross-sectional views of portions of one pixel illustrated in FIG. 8. FIGS. 9A-9E illustrate a connection electrode according to one or more embodiments on an enlarged cross section of the connection electrode CNE illustrated in FIG. 8. FIGS. 9A-9D illustrate shapes in which first connection electrodes CNE1, CNE1-1, CNE1-2, and CNE1-3 and a portion of the second connection electrode CNE2 are connected and briefly illustrate a shape of the second connection electrode CNE2. FIG. 9E illustrates a shape in which a first connection electrode CNE1-4, a second connection electrode CNE2-4, and a third connection electrode CNE3-4 are connected, illustrates a shape in which an upper portion of the first electrode AE is connected, and briefly illustrates a shape of the first electrode AE.

Referring to FIG. 9A, the buffer layer BFL may be disposed on the base layer SUB, and at least a portion of the first transistor T1 may be disposed on the buffer layer BFL. The first connection electrode CNE1 is connected to the first transistor T1 through the first contact hole CH1 provided in a lower insulating layer INS-a. The lower insulating layer INS-a may include the first insulating layer INS1, the second insulating layer INS2, the third insulating layer INS3, and/or the fourth insulating layer INS4 illustrated in FIG. 8.

The first connection electrode CNE1 is connected to the first transistor T1 and includes a plurality of connection layers CNL1, CNL2, and CNL3. The first connection electrode CNE1 includes an insulating pattern disposed on at least some of the connection layers CNL1, CNL2, and CNL3.

The first connection electrode CNE1 includes the first connection layer CNL1 disposed on the first transistor T1 and connected to the first transistor T1 and the second connection layer CNL2 disposed on the first connection layer CNL1. The first connection electrode CNE1 includes a first insulating pattern ILP1 disposed on the second connection layer CNL2.

The first connection layer CNL1 is connected to the first transistor T1 through the first contact hole CH1 provided in the lower insulating layer INS-a. A portion of the first connection layer CNL1 may be in contact with an upper surface of the first transistor T1 through the first contact hole CH1. A portion of the first connection layer CNL1 is disposed on an upper portion of the lower insulating layer INS-a. The first connection layer CNL1 includes a first lower portion CNL1-1 disposed on the lower insulating layer INS-a and a second lower portion CNL1-2, which is disposed in the first contact hole CH1, and of which a portion is disposed on the first transistor T1. The second lower portion CNL1-2 may be connected to the first lower portion CNL1-1 and have an integral shape, and the second lower portion CNL1-2 may correspond to a portion disposed in the first contact hole CH1 and having a step difference from the first lower portion CNL1-1.

The first connection layer CNL1 may include a transparent conductive oxide. The first connection layer CNL1 may include, for example, an indium tin oxide (ITO), an indium zinc oxide (IZO), a zinc oxide (ZnO), and/or an indium tin zinc oxide (ITZO). The first connection layer CNL1 may be a single layer made of a transparent conductive oxide. As the first connection layer CNL1 is made of a transparent conductive oxide, the lower insulating layer INS-a may be prevented from being etched during a process of forming the first connection electrode CNE1 while conductivity of the first connection electrode CNE1 is maintained.

The second connection layer CNL2 is disposed on the first connection layer CNL1. The second connection layer CNL2 may be directly disposed on the first connection layer CNL1. The second connection layer CNL2 includes a first portion CNL2-1 disposed on the first lower portion CNL1-1 of the first connection layer CNL1 and a second portion CNL2-2 disposed on the second lower portion CNL1-2 of the first connection layer CNL1. The second portion CNL2-2 is disposed on the second lower portion CNL1-2, and a portion thereof is disposed in (e.g., inside) the first contact hole CH1. The second portion CNL2-2 is connected to the first portion CNL2-1 and has an integral shape. As a portion of the second portion CNL2-2 is disposed in the first contact hole CH1, the second portion CNL2-2 and the first portion CNL2-1 have a step difference therebetween.

The second connection layer CNL2 includes a metal. The second connection layer CNL2 may include a conductive metal, and for example, the second connection layer CNL2 may include molybdenum, gold, silver, titanium, copper, aluminum, and/or alloys thereof.

A side surface CNL1-S of the first connection layer CNL1 and a side surface CNL2-S of the second connection layer CNL2 may be aligned with each other. The side surface CNL1-S of the first connection layer CNL1 and the side surface CNL2-S of the second connection layer CNL2 may provide a single alignment surface parallel in the third direction DR3. The side surface CNL1-S of the first connection layer CNL1 may be provided in the first lower portion CNL1-1, and the side surface CNL2-S of the second connection layer CNL2 may be provided in the first portion CNL2-1. In one or more embodiments, the second connection layer CNL2 including a metal is first formed in a first patterning process, and then the first connection layer CNL1 is formed in a second patterning process using the second connection layer CNL2 as a mask. Thus, the side surface CNL1-S of the first connection layer CNL1 and the side surface CNL2- S of the second connection layer CNL2 may be aligned with each other.

The first insulating pattern ILP1 is disposed on the second connection layer CNL2. The first insulating pattern ILP1 fills a space formed due to a step difference of an upper surface of the second connection layer CNL2. The first insulating pattern ILP1 may be directly disposed on a portion of the second connection layer CNL2. The first insulating pattern ILP1 is disposed on the second portion CNL2-2. A first upper surface US1 of the first insulating pattern ILP1 and a second upper surface US2 of the first portion CNL2-1 may be aligned with each other. That is, the first upper surface US1 and the second upper surface US2 may be parallel to each other to define one alignment surface. The first upper surface US1 of the first insulating pattern ILP1 and the second upper surface US2 of the first portion CNL2-1 may be collectively formed through a single patterning process, and thus a parallel alignment surface may be defined.

The first insulating pattern ILP1 overlaps the second portion CNL2-2 on a plane and does not overlap the first portion CNL2-1 on a plane (e.g., the first insulating pattern ILP1 overlaps the second portion CNL2-2 in the third direction DR3 and does not overlap the first portion CNL2-1). The first insulating pattern ILP1 may be patterned to overlap only the second portion CNL2-2 disposed to correspond to the first contact hole CH1. The lower insulating layer INS-a includes an exposed upper surface INS-U that does not overlap the first connection layer CNL1 and the second connection layer CNL2, and the first insulating pattern ILP1 may not overlap the exposed upper surface INS-U on a plane (e.g., in a plan view).

The first insulating pattern ILP1 may include an inorganic insulating material. The first insulating pattern ILP1 may include an inorganic material including silicon. For example, the first insulating pattern ILP1 may include a silicon oxide, a silicon nitride, and/or a silicon oxy nitride.

The first contact hole CH1 may include an inner surface CH1-S having a suitable inclination (e.g., a predetermined inclination) with respect to the upper surface of the first transistor T1. The inner surface CH1-S may have an acute angle inclination.

The second lower portion CNL1-2 may include a (2-1)^{th} lower portion CNL1-21 disposed on the inner surface CH1-S of the first contact hole CH1 and a (2-2)^{th} lower portion CNL1-22 disposed on the upper surface of the first transistor T1. The second portion CNL2-2 may include a (2-1)^{th} portion CNL2-21 disposed on the inner surface CH1-S of the first contact hole CH1 and a (2-2)^{th} portion CNL2-22 disposed on the upper surface of the first transistor T1. The (2-1)^{th} portion CNL2-21 may be disposed on the (2-1)^{th} lower portion CNL1-21, and the (2-2)^{th} portion CNL2-22 may be disposed on the (2-2)^{th} lower portion CNL1-22.

The first insulating pattern ILP1 may fill a space defined by the (2-1)^{th} portion CNL2-21 and the (2-2)^{th} portion CNL2-22. The first insulating pattern ILP1 may be in contact with the (2-1)^{th} portion CNL2-21 and the (2-2)^{th} portion CNL2-22.

In one pixel included in the display panel according to one or more embodiments, the first connection electrode CNE1, which electrically connects the transistor and the light emitting element, includes the first connection layer CNL1 including a transparent conductive oxide and the second connection layer CNL2 including a metal and further includes the first insulating pattern ILP1 for removing a step difference of a portion of the first connection layer CNL1 and the second connection layer CNL2, which is disposed in (e.g., inside) the first contact hole CH1, to form the step difference. Accordingly, when the display panel according to one or more embodiments is applied to an electronic device requiring high resolution such as a head mounted display device, connection stability of the first connection electrode CNE1 may be improved. Accordingly, reliability of the display panel and the electronic device including the same may be improved.

The first connection electrode CNE1 may further include the third connection layer CNL3 disposed on the second connection layer CNL2, the first insulating pattern ILP1, and the lower insulating layer INS-a. The third connection layer CNL3 may be disposed on the first upper surface US1 of the first insulating pattern ILP1 and the second upper surface US2 of the first portion CNL2-1. The third connection layer CNL3 may be directly disposed on the first upper surface US1 of the first insulating pattern ILP1 and the second upper surface US2 of the first portion CNL2-1 and thus may be in contact with the first insulating pattern ILP1 and the first portion CNL2-1.

The third connection layer CNL3 may include a metal. The third connection layer CNL3 may include a conductive metal, and for example, the third connection layer CNL3 may include molybdenum, gold, silver, titanium, copper, aluminum, and/or alloys thereof.

The third connection layer CNL3 may overlap at least a portion of the first portion CNL2-1 of the second connection layer CNL2 and may be in contact with the first portion CNL2-1. For example, as illustrated in FIG. 9A, the third connection layer

CNL3 may entirely overlap the second connection layer CNL2 and may also overlap the exposed upper surface INS-U of the lower insulating layer INS-a. The third connection layer CNL3 may include a first connection portion CNL3-1 disposed on the first upper surface US1 and the second upper surface US2 and a second connection portion CNL3-2 disposed on the exposed upper surface INS-U of the lower insulating layer INS-a. The third connection layer CNL3 may be formed to have a large area provided as a common layer in the remaining area in addition to an area in which the conductive pattern such as the second gate electrode G2 (see FIG. 8) is formed. As the first connection electrode CNE1 according to one or more embodiments further includes the third connection layer CNL3, a wide area for forming an electrical connection structure with the second connection electrode CNE2 and/or the like disposed thereon may be secured, and thus the connection stability may be further improved.

A first upper insulating layer INS-b may be disposed on the first connection electrode CNE1, and the first upper insulating layer INS-b may cover at least a portion of the first connection electrode CNE1. The first upper insulating layer INS-b may include the fifth insulating layer INS5 (see FIG. 8). The second contact hole CH2 may be provided in the first upper insulating layer INS-b, and a portion of the first connection electrode CNE1 may be exposed by the second contact hole CH2. In one or more embodiments, the first upper insulating layer INS-b may cover a portion of an upper surface of the third connection layer CNL3, and the remaining portion of the third connection layer CNL3 may be exposed by the second contact hole CH2. The second connection electrode CNE2 may be connected to the first connection electrode CNE1 through the second contact hole CH2.

Referring to FIG. 9B, unlike the illustration of FIG. 9A, a third connection layer CNL3a included in the first connection electrode CNE1-1 may not be provided as a common layer but may include a first connection portion CNL3-1 disposed on the second connection layer CNL2 and the first insulating pattern ILP1 and a second connection portion CNL3-2a extending from the first connection portion CNL3-1. The second connection portion CNL3-2a may be patterned to overlap only a portion of the exposed upper surface INS-U of the lower insulating layer INS-a.

The first upper insulating layer INS-b may be disposed on the first connection electrode CNE1-1, and the first upper insulating layer INS-b may cover at least a portion of the first connection electrode CNE1-1. The second contact hole CH2 may be provided in the first upper insulating layer INS-b, and a portion of the first connection electrode CNE1-1 may be exposed by the second contact hole CH2. In one or more embodiments, the first upper insulating layer INS-b may cover a portion of an upper surface of the third connection layer CNL3a, and the remaining portion of the third connection layer CNL3a may be exposed by the second contact hole CH2. The first upper insulating layer INS-b may be in contact with a portion of the exposed upper surface INS-U of the lower insulating layer INS-a in which the second connection portion CNL3-2a is not disposed.

Referring to FIG. 9C, unlike the illustration of FIG. 9A, a third connection layer CNL3b included in the first connection electrode CNE1-2 may not be provided as a common layer but may be provided as a conductive pattern overlapping only the portion of the second connection layer CNL2. The third connection layer CNL3b may overlap the first insulating pattern ILP1, overlap only the portion of the second connection layer CNL2, and may not overlap the remaining portion thereof. The third connection layer CNL3b may not be disposed on the exposed upper surface INS-U of the lower insulating layer INS-a and may not overlap the exposed upper surface INS-U on a plane (e.g., in a plan view).

The first upper insulating layer INS-b may be disposed on the first connection electrode CNE1-2, and the first upper insulating layer INS-b may cover at least a portion of the first connection electrode CNE1-2. The second contact hole CH2 may be provided in the first upper insulating layer INS-b, and a portion of the first connection electrode CNE1-2 may be exposed by the second contact hole CH2. In one or more embodiments, the first upper insulating layer INS-b may cover a portion of an upper surface of the third connection layer CNL3b, and the remaining portion of the third connection layer CNL3b may be exposed by the second contact hole CH2. The first upper insulating layer INS-b may be in contact with the exposed upper surface INS-U of the lower insulating layer INS-a in which the third connection layer CNL3b is not disposed and the portion of the first portion CNL2-1 of the second connection layer CNL2.

Referring to FIG. 9D, unlike the illustration of FIG. 9A, the first connection electrode CNE1-3 may not include a third connection layer. As the third connection layer is omitted, the first upper insulating layer INS-b disposed on the first connection electrode CNE1-3 may cover the portion of the second connection layer CNL2. The second contact hole CH2 may be provided in the first upper insulating layer INS-b, the first upper surface US1 of the first insulating pattern ILP1 may be exposed by the second contact hole CH2, and a portion of the second upper surface US2 of the second connection layer CNL2 may be exposed. In one or more embodiments, the first upper insulating layer INS-b may cover a portion of the upper surface of the second connection layer CNL2, and the remaining portion of the second connection layer CNL2 may be exposed by the second contact hole CH2. The first upper insulating layer INS-b may be in contact with the exposed upper surface INS-U of the lower insulating layer INS-a and the portion of the first portion CNL2-1 of the second connection layer CNL2.

Referring to FIG. 9E, the first connection electrode CNE1-4 is connected to the first transistor T1 through the first contact hole CH1 provided in the lower insulating layer INS-a. The second connection electrode CNE2-4 may be connected to the first connection electrode CNE1-4 through the second contact hole CH2 provided in the first upper insulating layer INS-b. The third connection electrode CNE3-4 may be connected to the second connection electrode CNE2-4 through the third contact hole CH3 provided in a second upper insulating layer INS-c. The first upper insulating layer

INS-b may include the fifth insulating layer INS5 (see FIG. 8). The second upper insulating layer INS-c may include the sixth insulating layer INS6 (see FIG. 8).

As described in FIGS. 9A and 9B, the first connection electrode CNE1-4 may include the first connection layer CNL1, the second connection layer CNL2, the first insulating pattern ILP1, and the third connection layer CNL3a.

The second connection electrode CNE2-4 may be connected to the first connection electrode CNE1-4 through the second contact hole CH2. The second connection electrode CNE2-4 may have a laminated structure similar to that of the first connection electrode CNE1-4.

The second connection electrode CNE2-4 may include a first additional connection layer CNLa1 disposed on the first connection electrode CNE1-4 and electrically connected to the first connection electrode CNE1-4 and a second additional connection layer CNLa2 disposed on the first additional connection layer CNLa1. The second connection electrode CNE2-4 may include a second insulating pattern ILP2 disposed on the second additional connection layer CNLa2.

The first additional connection layer CNLa1 may be connected to the first connection electrode CNE1-4 through the second contact hole CH2 provided in the first upper insulating layer INS-b. A portion of the first additional connection layer CNLa1 may be in contact with the upper surface of the third connection layer CNL3a of the first connection electrode CNE1-4 through the second contact hole CH2. A portion of the first additional connection layer CNLa1 is disposed on the first upper insulating layer INS-b. The first additional connection layer CNLa1 may include a first additional lower portion CNLa1-1 disposed on the first upper insulating layer INS-b and a second additional lower portion CNLa1-2, which is disposed in the second contact hole CH2, and of which a portion is disposed on the third connection layer CNL3a. The second additional lower portion CNLa1-2 may be connected to the first additional lower portion CNLa1-1 and have an integral shape, and the second additional lower portion CNLa1-2 may correspond to a portion disposed in the second contact hole CH2 and having a step difference from the first additional lower portion CNLa1-1.

The first additional connection layer CNLa1 may include a transparent conductive oxide. The first additional connection layer CNLa1 may include, for example, an indium tin oxide (ITO), an indium zinc oxide (IZO), a zinc oxide (ZnO), and/or an indium tin zinc oxide (ITZO). The first additional connection layer CNLa1 may be a single layer made of a transparent conductive oxide. As the first additional connection layer CNLa1 is made of a transparent conductive oxide, the first upper insulating layer INS-b may be prevented from being etched during a process of forming the second connection electrode CNE2-4 while conductivity of the second connection electrode CNE2-4 is maintained.

The second additional connection layer CNLa2 may be disposed on the first additional connection layer CNLa1. The second additional connection layer CNLa2 may be directly disposed on the first additional connection layer CNLa1. The second additional connection layer CNLa2 may include a first additional portion CNLa2-1 disposed on the first additional lower portion CNLa1-1 of the first additional connection layer CNLa1 and a second additional portion CNLa2-2 disposed on the second additional lower portion CNLa1-2 of the first additional connection layer CNLa1. The second additional portion CNLa2-2 may be disposed on the second additional lower portion CNLa1-2, and a portion thereof may be disposed in the second contact hole CH2. The second additional portion CNLa2-2 may be connected to the first additional portion CNLa2-1 and have an integral shape. As a portion of the second additional portion CNLa2-2 is disposed in the second contact hole CH2, the second additional portion CNLa2-2 and the first additional portion CNLa2-1 may have a step difference therebetween.

The second additional connection layer CNLa2 may include a metal. The second additional connection layer CNLa2 may include a conductive metal, and for example, the second additional connection layer CNLa2 may include molybdenum, gold, silver, titanium, copper, aluminum, and/or alloys thereof.

A side surface CNLa1-S of the first additional connection layer CNLa1 and a side surface CNLa2-S of the second additional connection layer CNLa2 may be aligned with each other. The side surface CNLa1-S of the first additional connection layer CNLa1 and the side surface CNLa2-S of the second additional connection layer CNLa2 may provide a single alignment surface parallel in the third direction DR3. In one or more embodiments, the second additional connection layer CNLa2 including a metal is first formed in the first patterning process, and then the first additional connection layer CNLa1 is formed in the second patterning process using the second additional connection layer CNLa2 as a mask. Thus, the side surface CNLa1-S of the first additional connection layer CNLa1 and the side surface CNLa2-S of the second additional connection layer CNLa2 may be aligned with each other.

The second insulating pattern ILP2 may be disposed on the second additional connection layer CNLa2. The second insulating pattern ILP2 may fill a space formed due to a step difference of an upper surface of the second additional connection layer CNLa2. The second insulating pattern ILP2 may be directly disposed on a portion of the second additional connection layer CNLa2. The second insulating pattern ILP2 may be disposed on the second additional portion CNLa2-2. A third upper surface US3 of the second insulating pattern ILP2 and a fourth upper surface US4 of the first additional portion CNLa2-1 may be aligned with each other. That is, the third upper surface US3 and the fourth upper surface US4 may be parallel to each other to define one alignment surface. The third upper surface US3 of the second insulating pattern ILP2 and the fourth upper surface US4 of the first additional portion CNLa2-1 may be collectively formed through a single patterning process, and thus a parallel alignment surface may be defined.

The second insulating pattern ILP2 may overlap the second additional portion CNLa2-2 on a plane and may not overlap the first additional portion CNLa2-1 on a plane (e.g., the second insulating pattern ILP2 may overlap the second additional portion CNLa2-2 in the third direction DR3 and may not overlap the first additional portion CNLa2-1). The second insulating pattern ILP2 may be patterned to overlap only the second additional portion CNLa2-2 disposed to correspond to the second contact hole CH2. The first upper insulating layer INS-b may include an exposed upper surface INSb-U that does not overlap the first additional connection layer CNLa1 and the second additional connection layer CNLa2, and the second insulating pattern ILP2 may not overlap the exposed upper surface INSb-U on a plane (e.g., in a plan view).

The second insulating pattern ILP2 may include an inorganic insulating material. The second insulating pattern ILP2 may include an inorganic material including silicon. For example, the second insulating pattern ILP2 may include a silicon oxide, a silicon nitride, and/or a silicon oxy nitride.

The second connection electrode CNE2-4 may further include a third additional connection layer CNLa3 disposed on the second additional connection layer CNLa2, the second insulating pattern ILP2, and the first upper insulating layer INS-b. The third additional connection layer CNLa3 may be disposed on the third upper surface US3 of the second insulating pattern ILP2 and the fourth upper surface US4 of the first additional portion CNLa2-1. For example, the third additional connection layer CNLa3 may be directly disposed on the third upper surface US3 of the second insulating pattern ILP2 and the fourth upper surface US4 of the first additional portion CNLa2-1 and thus may be in contact with the second insulating pattern ILP2 and the first additional portion CNLa2-1.

The third additional connection layer CNLa3 may include a metal. The third additional connection layer CNLa3 may include a conductive metal, and for example, the third additional connection layer CNLa3 may include molybdenum, gold, silver, titanium, copper, aluminum, and/or alloys thereof.

The third additional connection layer CNLa3 may overlap at least a portion of the first additional portion CNLa2-1 of the second additional connection layer CNLa2 and may be in contact with the first additional portion CNLa2-1. For example, as illustrated in FIG. 9E, the third additional connection layer CNLa3 may entirely overlap the second additional connection layer CNLa2 and may also overlap the exposed upper surface INSb-U of the first upper insulating layer INS-b. The third additional connection layer CNLa3 may include a first additional connection portion CNLa3-1 disposed on the third upper surface US3 and the fourth upper surface US4 and a second additional connection portion CNLa3-2a extending from the first additional connection portion CNLa3-1. The second additional connection portion CNLa3-2a may be patterned to overlap only a portion of the exposed upper surface INSb-U of the first upper insulating layer INS-b. As the second connection electrode CNE2-4 according to one or more embodiments further includes the third additional connection layer CNLa3, a wide area for forming an electrical connection structure with the third connection electrode CNE3-4 and/or the like disposed thereon may be secured, and thus the connection stability may be further improved.

The second upper insulating layer INS-c may be disposed on the second connection electrode CNE2-4, and the second upper insulating layer INS-c may cover at least a portion of the second connection electrode CNE2-4. The third contact hole CH3 may be provided in the second upper insulating layer INS-c, and a portion of the second connection electrode CNE2-4 may be exposed by the third contact hole CH3.

In one or more embodiments, the second upper insulating layer INS-c may cover a portion of an upper surface of the third additional connection layer CNLa3, and the remaining portion of the third additional connection layer CNLa3 may be exposed by the third contact hole CH3. The second upper insulating layer INS-c may be in contact with a portion of the exposed upper surface INSb-U of the first upper insulating layer INS-b in which the second additional connection portion CNLa3-2a is not disposed.

The third connection electrode CNE3-4 may be connected to the second connection electrode CNE2-4 through the third contact hole CH3. The third connection electrode CNE3-4 may have a laminated structure similar to those of the first connection electrode CNE1-4 and the second connection electrode CNE2-4.

The third connection electrode CNE3-4 may include a fourth additional connection layer CNLa4 disposed on the second connection electrode CNE2-4 and electrically connected to the second connection electrode CNE2-4 and a fifth additional connection layer CNLa5 disposed on the fourth additional connection layer CNLa4. The third connection electrode CNE3-4 may include a third insulating pattern ILP3 disposed on the fifth additional connection layer CNLa5.

The fourth additional connection layer CNLa4 may be connected to the second connection electrode CNE2-4 through the third contact hole CH3 provided in the second upper insulating layer INS-c. A portion of the fourth additional connection layer CNLa4 may be in contact with the upper surface of the third additional connection layer CNLa3 of the second connection electrode CNE2-4 through the third contact hole CH3. A portion of the fourth additional connection layer CNLa4 is disposed on the second upper insulating layer INS-c. The fourth additional connection layer CNLa4 may include a third additional lower portion CNLa4-1 disposed on the second upper insulating layer INS-c and a fourth additional lower portion CNLa4-2, which is disposed in the third contact hole CH3, and of which a portion is disposed on the third additional connection layer CNLa3. The fourth additional lower portion CNLa4-2 may be connected to the third additional lower portion CNLa4-1 and have an integral shape, and the fourth additional lower portion CNLa4-2 may correspond to a portion disposed in the third contact hole CH3 and having a step difference from the third additional lower portion CNLa4-1.

The fourth additional connection layer CNLa4 may include a transparent conductive oxide. The fourth additional connection layer CNLa4 may include, for example, an indium tin oxide (ITO), an indium zinc oxide (IZO), a zinc oxide (ZnO), and/or an indium tin zinc oxide (ITZO). The fourth additional connection layer CNLa4 may be a single layer made of a transparent conductive oxide. As the fourth additional connection layer CNLa4 is made of a transparent conductive oxide, the second upper insulating layer INS-c may be prevented from being etched during a process of forming the third connection electrode CNE3-4 while conductivity of the third connection electrode CNE3-4 is maintained.

The fifth additional connection layer CNLa5 may be disposed on the fourth additional connection layer CNLa4. The fifth additional connection layer CNLa5 may be directly disposed on the fourth additional connection layer CNLa4. The fifth additional connection layer CNLa5 may include a third additional portion CNLa5-1 disposed on the third additional lower portion CNLa4-1 of the fourth additional connection layer CNLa4 and a fourth additional portion CNLa5-2 disposed on the fourth additional lower portion CNLa4-2 of the fourth additional connection layer CNLa4. The fourth additional portion CNLa5-2 may be disposed on the fourth additional lower portion CNLa4-2, and a portion thereof may be disposed in the third contact hole CH3. The fourth additional portion CNLa5-2 may be connected to the third additional portion CNLa5-1 and have an integral shape. As a portion of the fourth additional portion CNLa5-2 is disposed in the third contact hole CH3, the fourth additional portion CNLa5-2 and the third additional portion CNLa5-1 may have a step difference therebetween.

The fifth additional connection layer CNLa5 may include a metal. The fifth additional connection layer CNLa5 may include a conductive metal, and for example, the fifth additional connection layer CNLa5 may include molybdenum, gold, silver, titanium, copper, aluminum, and/or alloys thereof.

A side surface CNLa4-S of the fourth additional connection layer CNLa4 and a side surface CNLa5-S of the fifth additional connection layer CNLa5 may be aligned with each other. The side surface CNLa4-S of the fourth additional connection layer CNLa4 and the side surface CNLa5-S of the fifth additional connection layer CNLa5 may provide a single alignment surface parallel in the third direction DR3. In one or more embodiments, the fifth additional connection layer CNLa5 including a metal is first formed in the first patterning process, and then the fourth additional connection layer CNLa4 is formed in the second patterning process using the fifth additional connection layer CNLa5 as a mask. Thus, the side surface CNLa4-S of the fourth additional connection layer CNLa4 and the side surface CNLa5-S of the fifth additional connection layer CNLa5 may be aligned with each other.

The third insulating pattern ILP3 may be disposed on the fifth additional connection layer CNLa5. The third insulating pattern ILP3 may fill a space formed due to a step difference of an upper surface of the fifth additional connection layer CNLa5.

The third insulating pattern ILP3 may be directly disposed on a portion of the fifth additional connection layer CNLa5. The third insulating pattern ILP3 may be disposed on the fourth additional portion CNLa5-2. A fifth upper surface US5 of the third insulating pattern ILP3 and a sixth upper surface US6 of the third additional portion CNLa5-1 may be aligned with each other. That is, the fifth upper surface US5 and the sixth upper surface US6 may be parallel to each other to define one alignment surface. The fifth upper surface US5 of the third insulating pattern ILP3 and the sixth upper surface US6 of the third additional portion CNLa5-1 may be collectively formed through a single patterning process, and thus a parallel alignment surface may be defined.

The third insulating pattern ILP3 may overlap the fourth additional portion CNLa5-2 on a plane and may not overlap the third additional portion CNLa5-1 on a plane (e.g., the third insulating pattern ILP3 may overlap the fourth additional portion CNLa5-2 in the third direction DR3 and may not overlap the third additional portion CNLa5-1). The third insulating pattern ILP3 may be patterned to overlap only the fourth additional portion CNLa5-2 disposed to correspond to the third contact hole CH3. The second upper insulating layer INS-c may include an exposed upper surface INSc-U that does not overlap the fourth additional connection layer CNLa4 and the fifth additional connection layer CNLa5, and the third insulating pattern ILP3 may not overlap the exposed upper surface INSc-U on a plane (e.g., in a plan view).

The third insulating pattern ILP3 may include an inorganic insulating material. The third insulating pattern ILP3 may include an inorganic material including silicon. For example, the third insulating pattern ILP3 may include a silicon oxide, a silicon nitride, and/or a silicon oxy nitride.

The third connection electrode CNE3-4 may further include a sixth additional connection layer CNLa6 disposed on the fifth additional connection layer CNLa5, the third insulating pattern ILP3, and the second upper insulating layer INS-c. The sixth additional connection layer CNLa6 may be disposed on the fifth upper surface US5 of the third insulating pattern ILP3 and the sixth upper surface US6 of the third additional portion CNLa5-1. For example, the sixth additional connection layer CNLa6 may be directly disposed on the fifth upper surface US5 of the third insulating pattern ILP3 and the sixth upper surface US6 of the third additional portion CNLa5-1 and thus may be in contact with the third insulating pattern ILP3 and the third additional portion CNLa5-1.

The sixth additional connection layer CNLa6 may include a metal. The sixth additional connection layer CNLa6 may include a conductive metal, and for example, the sixth additional connection layer CNLa6 may include molybdenum, gold, silver, titanium, copper, aluminum, and/or alloys thereof.

The sixth additional connection layer CNLa6 may overlap at least a portion of the third additional portion CNLa5-1 of the fifth additional connection layer CNLa5 and may be in contact with the third additional portion CNLa5-1. For example, as illustrated in FIG. 9E, the sixth additional connection layer CNLa6 may entirely overlap the fifth additional connection layer CNLa5 and may also overlap the exposed upper surface INSc-U of the second upper insulating layer INS-c. The sixth additional connection layer CNLa6 may include a third additional connection portion CNLa6-1 disposed on the fifth upper surface US5 and the sixth upper surface US6 and a fourth additional connection portion CNLa6-2a extending from the third additional connection portion CNLa6-1. The fourth additional connection portion CNLa6-2a may be patterned to overlap only a portion of the exposed upper surface INSc-U of the second upper insulating layer INS-c. As the third connection electrode CNE3-4 according to one or more embodiments further includes the sixth additional connection layer CNLa6, a wide area for forming an electrical connection structure with the third connection electrode CNE3-4 and/or the like disposed thereon may be secured, and thus the connection stability may be further improved.

A third upper insulating layer INS-d may be disposed on the third connection electrode CNE3-4, and the third upper insulating layer INS-d may cover at least a portion of the third connection electrode CNE3-4. The third upper insulating layer INS-d may include the seventh insulating layer INS7 (see FIG. 8). The fourth contact hole CH4 may be provided in the third upper insulating layer INS-d, and a portion of the third connection electrode CNE3-4 may be exposed by the fourth contact hole CH4. In one or more embodiments, the third upper insulating layer INS-d may cover a portion of an upper surface of the sixth additional connection layer CNLa6, and the remaining portion of the sixth additional connection layer CNLa6 may be exposed by the fourth contact hole CH4. The third upper insulating layer INS-d may be in contact with a portion of the exposed upper surface INSc-U of the second upper insulating layer INS- c in which the fourth additional connection portion CNLa6-2a is not disposed. The first electrode AE of the light emitting element OLED (see FIG. 8) may be disposed on the third upper insulating layer INS-d, and the first electrode AE may be connected to the third connection electrode CNE3-4 through the fourth contact hole CH4 defined in the third upper insulating layer INS-d.

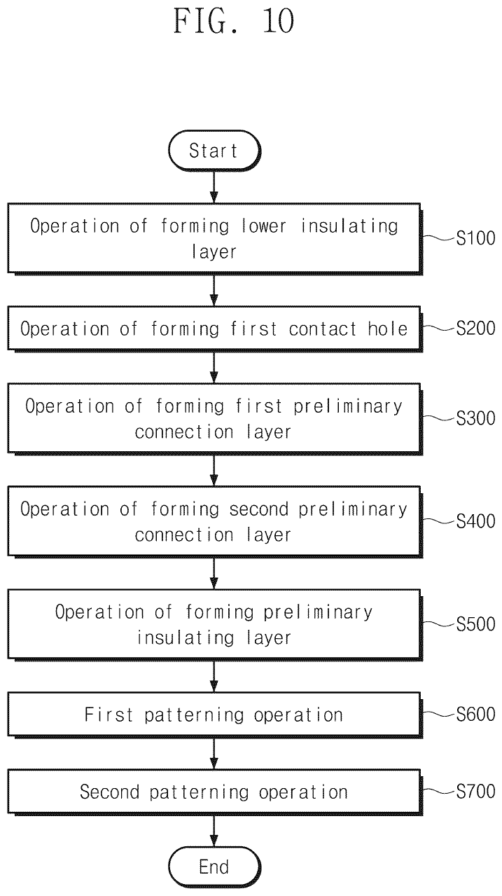

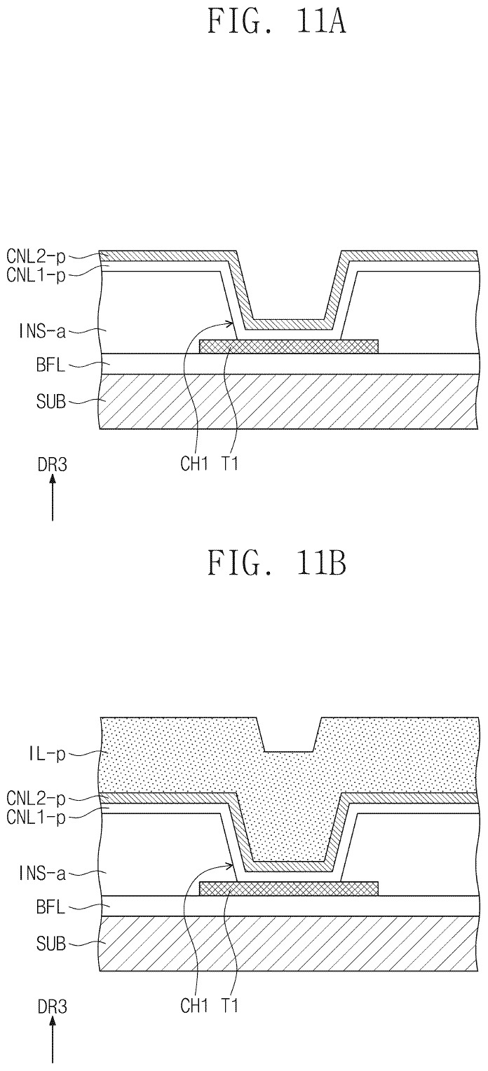

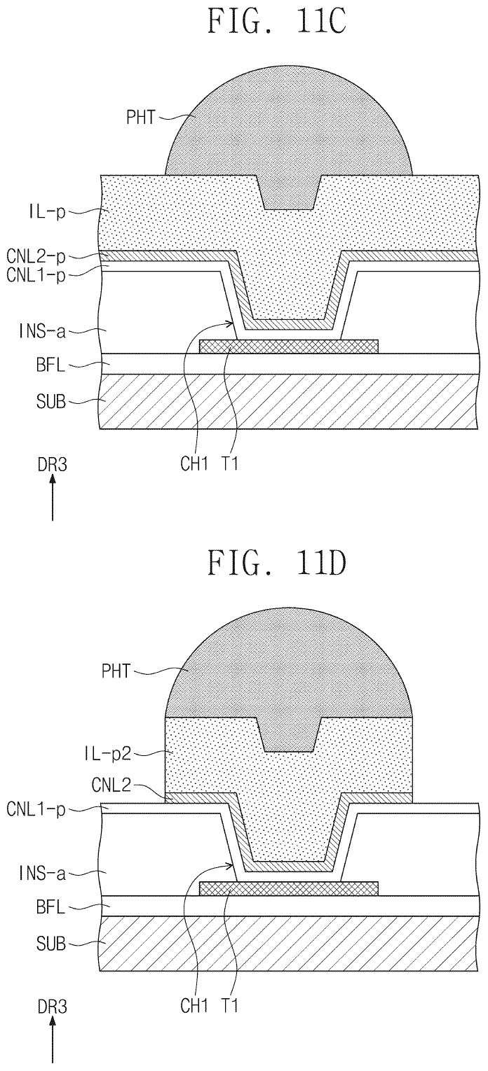

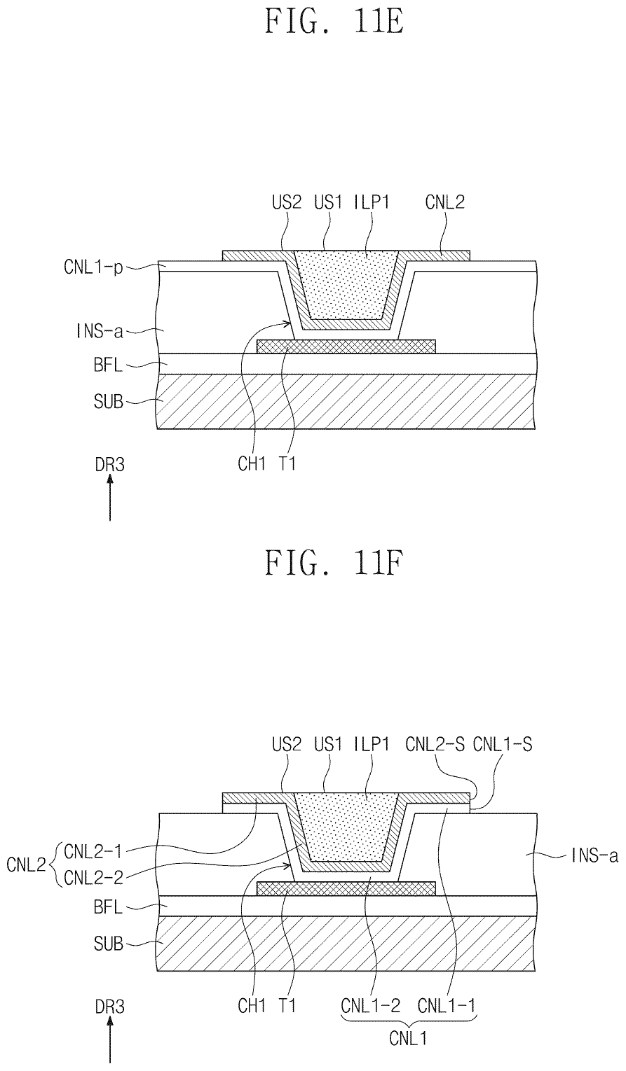

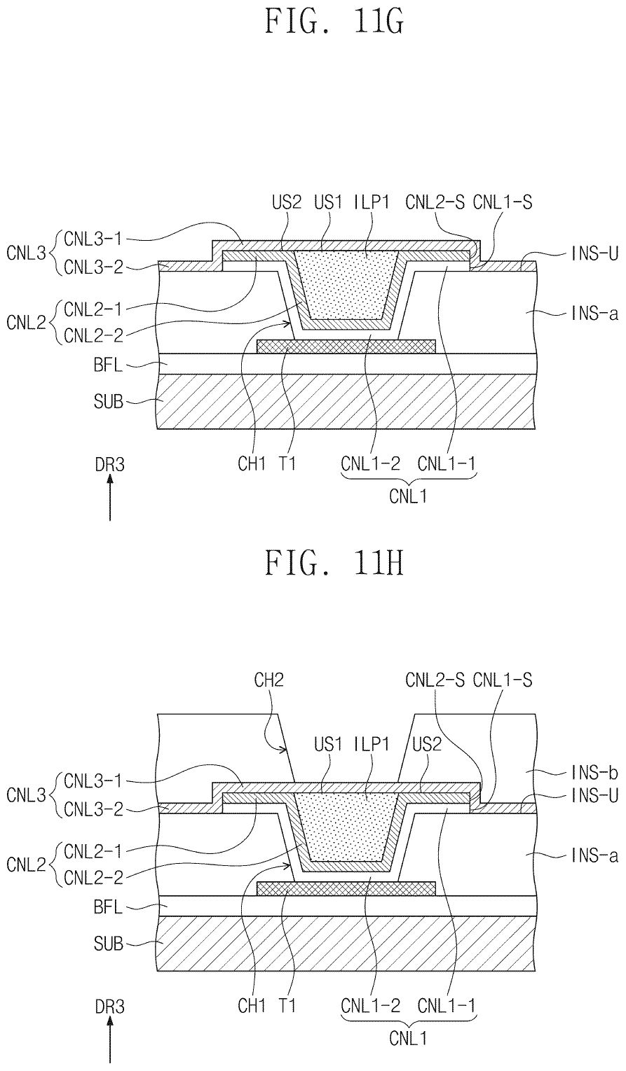

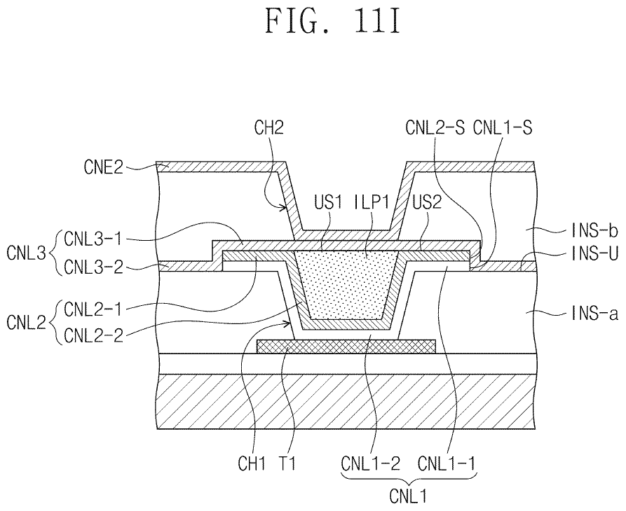

FIG. 10 is a flowchart of a method of manufacturing a display panel according to one or more embodiments. FIGS. 11A-11I are cross-sectional views sequentially illustrating operations of the method of manufacturing a display panel according to one or more embodiments. Hereinafter, in describing the method of manufacturing a display panel according to one or more embodiments with reference to FIGS. 10 and 11A-11I, the same reference numerals are given to the components described above with reference to FIGS. 1-9E, and a detailed description thereof will be omitted.

Referring to FIG. 10, the method of manufacturing a display panel according to one or more embodiment includes operation S100 of forming a lower insulating layer on a base layer in which a first transistor is disposed, operation S200 of forming a first contact hole, through which a portion of an upper surface of the first transistor is exposed, on the lower insulating layer, operation S300 of forming a first preliminary connection layer connected to the first transistor through the first contact hole on the lower insulating layer, operation S400 of forming a second preliminary connection layer including a metal on the first preliminary connection layer, operation S550 of forming a preliminary insulating layer on the second preliminary connection layer, first patterning operation S600 of patterning the preliminary insulating layer and the second preliminary connection layer to form a first insulating pattern and a second connection layer, and second patterning operation S700 of forming a first connection layer by patterning the first preliminary connection layer using the second connection layer as a mask.

Referring to FIGS. 10 and 11A, the method of manufacturing a display panel according to one or more embodiments includes the operation S100 of forming the lower insulating layer INS-a on the base layer SUB in which the first transistor T1 is disposed and the operation S200 of forming the first contact hole CH1, through which a portion of an upper surface of the first transistor T1 is exposed, on the lower insulating layer INS-a. The lower insulating layer INS-a may include the first insulating layer INS1, the second insulating layer INS2, the third insulating layer INS3, and/or the fourth insulating layer INS4 illustrated in FIG. 8.

The method of manufacturing a display panel according to one or more embodiments includes, after the operation S200 of forming the first contact hole CH1, the operation S300 of forming a first preliminary connection layer CNL1-p on the lower insulating layer INS-a and the operation S400 of forming a second preliminary connection layer CNL2-p on the first preliminary connection layer CNL1-p.

The first preliminary connection layer CNL1-p has a portion disposed in (e.g., inside) the first contact hole CH1 and is electrically connected to the first transistor T1. A portion of the first preliminary connection layer CNL1-p may be in contact with an upper surface of the first transistor T1 through the first contact hole CH1. The first preliminary connection layer CNL1-p may be entirely formed on the first transistor T1 and the lower insulating layer INS-a. The first preliminary connection layer CNL1-p may be formed of a transparent conductive oxide. For example, the first preliminary connection layer CNL1-p may be formed through an indium tin oxide (ITO), an indium zinc oxide (IZO), a zinc oxide (ZnO), and/or an indium tin zinc oxide (ITZO). The first preliminary connection layer CNL1-p may be formed as a single layer made of a transparent conductive oxide.

The second preliminary connection layer CNL2-p may be directly formed on the first preliminary connection layer CNL1-p. The second preliminary connection layer CNL2-p may be entirely formed on the first preliminary connection layer CNL1-p. The second preliminary connection layer CNL2-p may be in contact with an upper surface of the first preliminary connection layer CNL1-p. The second preliminary connection layer CNL2-p may be formed of a metal. The second preliminary connection layer CNL2-p may be formed of a conductive metal, and for example, the second preliminary connection layer CNL2-p may be formed of molybdenum, gold, silver, titanium, copper, aluminum, and/or alloys thereof.

Referring to FIGS. 10, 11A, and 11B, the method of manufacturing a display panel according to one or more embodiments includes the operation S500 of forming a preliminary insulating layer IL-p on the second preliminary connection layer CNL2-p.

The preliminary insulating layer IL-p may be directly formed on the second preliminary connection layer CNL2-p. The preliminary insulating layer IL-p may be entirely formed on the second preliminary connection layer CNL2-p. The preliminary insulating layer IL-p may be in contact with an upper surface of the second preliminary connection layer CNL2-p. The preliminary insulating layer IL-p may be formed of an inorganic insulating material. The preliminary insulating layer IL-p may be formed of an inorganic material including silicon. For example, the preliminary insulating layer IL-p may be formed of a silicon oxide, a silicon nitride, and/or a silicon oxy nitride. The preliminary insulating layer IL-p may be formed by a chemical vapor deposition method or a plasma-enhanced chemical vapor deposition method.

Referring to FIGS. 10, 11B-11E, the method of manufacturing a display panel according to one or more embodiments includes the first patterning operation S600 of patterning the preliminary insulating layer IL-p and the second preliminary connection layer CNL2-p to form the first insulating pattern ILP1 and the second connection layer CNL2.

In the first patterning operation S600, a photoresist pattern PHT may be formed on the preliminary insulating layer IL-p. The photoresist pattern PHT may be formed by applying a photoresist material onto the preliminary insulating layer IL-p, exposing a portion of the photoresist material, and then developing the portion of the photoresist material. The photoresist material may include a positive photoresist or a negative photoresist.

In the first patterning operation S600, after the photoresist pattern PHT is formed, portions of the preliminary insulating layer IL-p and the second preliminary connection layer CNL2-p may be etched together using the photoresist pattern PHT as a mask. After the etching process, a portion of the second preliminary connection layer CNL2-p including a metal may be etched to form the second connection layer CNL2, and a portion of the preliminary insulating layer IL-p including an inorganic insulating material may be etched to form an intermediate preliminary insulating layer IL-p 2.

In the first patterning operation S600, after the second connection layer CNL2 and the intermediate preliminary insulating layer IL-p 2 are formed, a portion of the intermediate preliminary insulating layer IL-p 2 may be etched to form the first insulating pattern ILP1. A process of forming the first insulating pattern ILP1 may be performed by removing an upper portion of the intermediate preliminary insulating layer IL-p2 through a chemical mechanical polishing (CMP) process or dry etching. As the upper portion of the intermediate preliminary insulating layer IL-p2 is removed through the CMP process or the dry etching, the first upper surface US1 of the first insulating pattern ILP1 and the second upper surface US2 of the first portion CNL2-1 may be aligned with each other after the first insulating pattern ILP1 is formed. The first upper surface US1 and the second upper surface US2 may be parallel to each other to define one alignment surface.

In the method of manufacturing a display panel according to one or more embodiments, the first preliminary connection layer CNL1-p may include a transparent conductive oxide and thus may not be etched in a process of etching portions of the preliminary insulating layer IL-p and the second preliminary connection layer CNL2-p using the photoresist pattern PHT as a mask and a process of etching a portion of the intermediate preliminary insulating layer IL-p2 to form the first insulating pattern ILP1. Thus, the first preliminary connection layer CNL1-p may remain on the lower insulating layer INS-a during the first patterning operation S600 to prevent the lower insulating layer INS-a from being etched.

Referring to FIGS. 10, 11E, and 11F together, the method of manufacturing a display panel according to one or more embodiments includes the second patterning operation S700 of forming the first connection layer CNL1 by patterning the first preliminary connection layer CNL1-p using the second connection layer CNL2 as a mask.

The first preliminary connection layer CNL1-p may be patterned through a wet etching process. In the operation of forming the first connection layer CNL1, the first preliminary connection layer CNL1-p may be etched using the second connection layer CNL2 disposed thereon as a mask, and thus the side surface CNL1-S of the first connection layer CNL1 and the side surface CNL2-S of the second connection layer CNL2 may provide a single alignment surface parallel in the third direction DR3.

After the second patterning operation S700, a structure in which the first connection layer CNL1, the second connection layer CNL2, and the first insulating pattern ILP1 are sequentially laminated is formed. The first connection layer CNL1 includes the first lower portion CNL1-1 disposed on the lower insulating layer INS-a and the second lower portion CNL1-2, which is disposed in the first contact hole CH1, and of which a portion is disposed on the first transistor T1. The second connection layer CNL2 includes the first portion CNL2-1 disposed on the first lower portion CNL1-1 of the first connection layer CNL1 and the second portion CNL2-2 disposed on the second lower portion CNL1-2 of the first connection layer CNL1. The first insulating pattern ILP1 fills a space formed due to a step difference of an upper surface of the second connection layer CNL2. The first insulating pattern ILP1 overlaps the second portion CNL2-2 on a plane and does not overlap the first portion CNL2-1 on a plane (e.g., the first insulating pattern ILP1 overlaps the second portion CNL2-2 in the third direction and does not overlap the first portion CNL2-1).

Referring to FIGS. 10, 11F, and 11G together, the method of manufacturing a display panel according to one or more embodiments may further include an operation of forming the third connection layer CNL3 on the second connection layer CNL2 and the first insulating pattern ILP1. The third connection layer CNL3 may be directly formed on the first upper surface US1 of the first insulating pattern ILP1 and the second upper surface US2 of the first portion CNL2-1 and thus may be in contact with the first insulating pattern ILP1 and the first portion CNL2-1. After the third connection layer CNL3 is formed, the first connection electrode CNE1 according to one or more embodiments may be formed.

The third connection layer CNL3 may be formed of a metal. The third connection layer CNL3 may be formed of a conductive metal, and for example, the third connection layer CNL3 may be formed of molybdenum, gold, silver, titanium, copper, aluminum, and/or alloys thereof.

The third connection layer CNL3 may overlap at least a portion of the first portion CNL2-1 of the second connection layer CNL2 and may be formed to be in contact with the first portion CNL2-1. For example, as illustrated in FIG. 11G, the third connection layer CNL3 may be entirely formed on the first insulating pattern ILP1 and the second connection layer CNL2 and may also be formed on the exposed upper surface INS-U of the lower insulating layer INS-a. The third connection layer CNL3 may include the first connection portion CNL3-1 disposed on the first upper surface US1 and the second upper surface US2 and the second connection portion CNL3-2 disposed on the exposed upper surface INS-U of the lower insulating layer INS-a. As the first connection electrode CNE1 according to one or more embodiments further includes the third connection layer CNL3, a wide area for forming an electrical connection structure with the second connection electrode CNE2 and/or the like disposed thereon may be secured, and thus the connection stability may be further improved. In one or more embodiments, the method of manufacturing a display panel according to one or more embodiments may further include an operation of forming the connection portions CNL3a and CNL3b as illustrated in FIGS. 9B and 9C by additionally patterning the third connection layer CNL3. The operation of forming the third connection layer CNL3 may be omitted.

Referring to FIGS. 10, 11G-11I together, the method of manufacturing a display panel according to one or more embodiments may further include an operation of forming the first upper insulating layer INS-b and the second connection electrode CNE2.

The first upper insulating layer INS-b may be formed on the third connection layer CNL3 and may cover a portion of the third connection layer CNL3. The first upper insulating layer INS-b may include the fifth insulating layer INS5 (see FIG. 8). The second contact hole CH2 may be formed in the first upper insulating layer INS-b, and the portion of the third connection layer CNL3 may be exposed by the second contact hole CH2. In one or more embodiments, the first upper insulating layer INS-b may cover the portion of the upper surface of the third connection layer CNL3, and the remaining portion of the third connection layer CNL3 may be exposed by the second contact hole CH2. The second connection electrode CNE2 may be formed to be connected to the first connection electrode CNE1 through the second contact hole CH2. FIG. 11I briefly illustrates a shape of the second connection electrode CNE2, but the second connection electrode CNE2 may also be formed through a process similar to the process of forming the first connection electrode CNE1.

In a display panel according to one or more embodiments, a step difference, which is formed as some of a plurality of conductive layers included in a connection electrode are arranged in (e.g., inside) a contact hole, may be removed, and thus contact stability of the connection electrode may be improved. Further, a lower insulating layer may be prevented from being etched together in a process of forming a step difference removing structure, and thus reliability of the display panel manufactured through the manufacturing method according to one or more embodiments may be improved.

Although the description has been made above with reference to an embodiment of the present disclosure, those skilled in the art may understand that the present disclosure may be variously modified and changed without departing from the spirit and the technical scope of the present disclosure described in the appended claims and their equivalents.

Thus, the technical scope of the present disclosure should not be limited to the contents described in the detailed description of the specification but may be defined by the appended claims and their equivalents.

1 what is claimed is:

1. A display panel comprising:
a first transistor;
a lower insulating layer on the first transistor;
a first connection electrode on the lower insulating layer and connected to the first transistor through a first contact hole in the lower insulating layer; and
a light emitting element on the first connection electrode and comprising an anode electrically connected to the first connection electrode,
wherein the first connection electrode comprises:
a first connection layer having a portion in the first contact hole and connected to the first transistor;
a second connection layer on the first connection layer and comprising a metal; and
a first insulating pattern on the second connection layer,
wherein the second connection layer comprises:
a first portion on the lower insulating layer; and
a second portion connected to the first portion, the second portion having a portion in the first contact hole, and has a step difference from the first portion,
wherein the first insulating pattern is on the second portion, and
wherein a first upper surface of the first insulating pattern is aligned with a second upper surface of the first portion.

2. The display panel of claim 1, wherein the first insulating pattern comprises at least one of a silicon oxide, a silicon nitride, or a silicon oxy nitride.

3. The display panel of claim 1, wherein the first connection electrode further comprises a third connection layer on the first upper surface and the second upper surface, the third connection layer comprising a metal.

4. The display panel of claim 3, wherein the third connection layer comprises:
a first connection portion disposed on the first upper surface and the second upper surface; and
a second connection portion connected to the first portion and located on an upper surface of the lower insulating layer.

5. The display panel of claim 3, wherein the lower insulating layer includes an exposed upper surface not overlapping the first connection layer and the second connection layer, and
wherein the third connection layer is on the first upper surface and the second upper surface and does not overlap the exposed upper surface of the lower insulating layer.

6. The display panel of claim 1, further comprising:
a first upper insulating layer on the first connection electrode; and
a second connection electrode on the first upper insulating layer and connected to the first connection electrode through a second contact hole in the first upper insulating layer.

7. The display panel of claim 6, wherein the second connection electrode comprises:
a first additional connection layer in the second contact hole and connected to the first connection electrode;
a second additional connection layer on the first additional connection layer and comprising a metal; and
a second insulating pattern on the second additional connection layer.

8. The display panel of claim 1, wherein the second connection layer is directly on the first connection layer, and the first insulating pattern is directly on the second connection layer.

9. The display panel of claim 1, wherein the first connection layer comprises a transparent conductive oxide.

10. The display panel of claim 1, wherein the light emitting element further comprises:
a light emitting layer on the anode; and
a cathode on the light emitting layer.

11. The display panel of claim 1, wherein the first contact hole includes an inner surface having a predetermined inclination with respect to an upper surface of the first transistor, and
wherein the second portion comprises:
a (2-1)^{th} portion on the inner surface of the first contact hole; and
a (2-2)^{th} portion disposed on the upper surface of the first transistor, and
wherein the first insulating pattern fills a space defined by the (2-1)^{th} portion and the (2-2)^{th} portion.

12. The display panel of claim 1, wherein the lower insulating layer includes an exposed upper surface not overlapping the first connection layer and the second connection layer, and
wherein the first insulating pattern does not overlap the exposed upper surface on a plane.

13. The display panel of claim 1, further comprising:
a second transistor on a layer between the first transistor and the light emitting element, connected to a first gate electrode of the first transistor and a data line, and switched by a write scan signal,
wherein a portion of the first connection electrode is on a same layer as a second gate electrode of the second transistor.

14. The display panel of claim 1, wherein a side surface of the first connection layer and a side surface of the second connection layer are aligned with each other.

15. An electronic device comprising:
a display panel; and
a case in which the display panel is accommodated,
wherein the display panel comprises:
a first transistor;
a lower insulating layer on the first transistor;
a first connection electrode on the lower insulating layer and connected to the first transistor through a contact hole in the lower insulating layer; and
a light emitting element on the first connection electrode and comprising an anode electrically connected to the first connection electrode,
wherein the first connection electrode comprises:
a first connection layer in the contact hole and connected to the first transistor;
a second connection layer on the first connection layer; and
a first insulating pattern on the second connection layer,
wherein the second connection layer comprises:
a first portion on the lower insulating layer; and
a second portion connected to the first portion, located in the contact hole, and having a step difference from the first portion,
wherein the first insulating pattern is on the second portion, and
wherein a first upper surface of the first insulating pattern is aligned with a second upper surface of the first portion.

16. A method of manufacturing a display panel, the method comprising:
an operation of forming a lower insulating layer on a base layer on which a first transistor is located;
an operation of forming a first contact hole, through which a portion of an upper surface of the first transistor is exposed, on the lower insulating layer;
an operation of forming a first preliminary connection layer connected to the first transistor through the first contact hole on the lower insulating layer;
an operation of forming a second preliminary connection layer comprising a metal on the first preliminary connection layer;
an operation of forming a preliminary insulating layer on the second preliminary connection layer;
a first patterning operation of forming a first insulating pattern and a second connection layer by patterning the preliminary insulating layer and the second preliminary connection layer; and
a second patterning operation of forming a first connection layer by patterning the first preliminary connection layer using the second connection layer as a mask,
wherein the second connection layer comprises:
a first portion on the lower insulating layer; and
a second portion connected to the first portion, located in the first contact hole, and having a step difference from the first portion,
wherein the first insulating pattern is on the second portion, and
wherein a first upper surface of the first insulating pattern is aligned with a second upper surface of the first portion.

17. The method of claim 16, wherein the first patterning operation comprises an operation of etching portions of the preliminary insulating layer and the second preliminary connection layer together, and
wherein the second patterning operation comprises an operation of wet etching the first preliminary connection layer.

18. The method of claim 16, further comprising, after the second patterning operation:
an operation of forming a third connection layer on the first upper surface and the second upper surface, the third connection layer comprising a metal.

19. The method of claim 16, further comprising:
an operation of forming a first upper insulating layer on the second connection layer and the first insulating pattern and provided with a second contact hole; and
an operation of forming a second connection electrode electrically connected to the second connection layer through the second contact hole in the first upper insulating layer.

20. The method of claim 16, wherein, after the second patterning operation, a side surface of the first connection layer and a side surface of the second connection layer are aligned with each other.
